(19) United States
(12) Patent Application Publication
(10) Pub. No.: US 2011/0032668 A1
(43) Pub. Date: Feb. 10, 2011

(54) SLIDE-TYPE OPENING/CLOSING DEVICE AND PORTABLE ELECTRONIC APPARATUS

(76) Inventor: Han Sang Lee, Seoul (KR)

Correspondence Address: ROBERTS MLOTKOWSKI SAFRAN & COLE, P.C.;Intellectual Property Department, P.O. Box 10064, MCLEAN, VA, 22102-8064, US

(21) Appl. No.: 12/937,975

(22) PCT Filed: Apr. 15, 2009
(86) PCT No.: PCT/KR2009/001927

§ 371 Date: Oct. 14, 2010

(30) Foreign Application Priority Data
Apr. 23, 2008 (KR) 10-2008-0037698
Mar. 20, 2009 (KR) 10-2009-0023759

(51) Int. Cl. H05K 5/02; B65D 43/12

(52) U.S. Cl. 361/679.01; 220/345.1

(57) ABSTRACT

Disclosed is a slide-type opening/closing device, which includes: a base member, on which first guide parts are installed, a first sliding member having first guided parts, which are movably engaged with the first guide parts, and second guide parts installed on the first sliding member in a direction different from a guiding direction of the first guide parts; and a second sliding member having second guided parts movably engaged with the second guide parts. The slide-type opening/closing device allows a portable electronic apparatus to easily implement an opening/closing operation, in which a cover of the portable electronic apparatus can be opened in both directions, and when the cover is opened in one direction, the cover isn't allowed to be opened in the other direction, or the cover is allowed to be opened in each direction without any limitation.

### TECHNICAL FIELD

The present invention relates to a portable electronic apparatus and a slide-type opening/closing device for the apparatus, and more particularly to a slide opening/closing-type portable electronic apparatus and a slide-type opening/closing device for the apparatus.

### BACKGROUND ART

In general, ‘a portable electronic apparatus refers to an apparatus allowing a user to perform communication, play game, learn, listen to music, watch TV, etc. while carrying the apparatus.

Such portable electronic apparatuses include wireless mobile phones, PDAs, electronic calculators, electronic notes, MP3 players, notebooks, portable game players, etc. A portable electronic apparatus may also be called a portable terminal.

Such a portable electronic apparatus has functions that have been integrated and diversified. Therefore, when a user wants to perform a call function of the apparatus, the user has to open/close the cover of the apparatus in a up-down direction, and when the user wants to perform a game function, etc, through a key inputting operation, the user has to open/close the cover of the apparatus in a left-right direction.

### DISCLOSURE OF INVENTION

### Technical Problem

An object of the present invention is to provide a portable electronic apparatus, which can be opened/closed through a sliding operation in an up-down direction and also in a left-right direction.

Another object of the present invention is to provide a portable electronic apparatus, which has an uncomplicated structure and can be opened/closed in two-directions, that is, in an up-down direction and in a right-left direction.

Another object of the present invention is to provide a portable electronic apparatus which has an uncomplicated structure and can be opened/closed in two-directions, that is, in the first and second directions.

Another object of the present invention is to provide a slide opening/closing-type device, which can be opened/closed in the first and second directions and allows a second body to be erected on a slant, and a portable electronic apparatus.

Another object of the present invention is to provide a portable electronic apparatus, which prevents a cover of the apparatus from being opened in one direction when the cover has been opened in another direction.

Another object of the present invention is to provide a portable electronic apparatus, which can be selectively opened along a first direction or a second direction in a state where a cover is closed, and can be changed from a state where the apparatus is opened in the first direction to a state where it is opened in the second direction or can be changed in an opposite manner.

The inventor recognized that all conventional slide-type apparatuses have a problem in that each cover of the apparatus is opened/closed through movement along a linear path so that the apparatuses has the same feel caused when the apparatuses are opened/closed and their opening/closing operations also do not accord with the movement of fingers.

Another object of the present invention is to provide a slide opening/closing device, which allows a cover of an apparatus to be opened along a curve path, and the apparatus.

Another object of the present invention is to provide a slide opening/closing-type device allowing paths, in which the cover of the apparatus is opened/closed, to be variously designed and the apparatus.

Another object of the present invention is to provide a slide opening/closing-type device and an apparatus, which has various opening/closing paths of a cover of the apparatus and various opened/closed states thereof.

Another object of the present invention is to provide a slide opening/closing-type device and an apparatus, which can operate with the shortest distance in a diagonal direction when the apparatus is opened in a second direction in a state where the apparatus has been opened in a first direction or in an opposite manner.

Another object of the present invention is to provide a slide opening/closing-type device, which allows a portable electronic apparatus according to the present invention to be implemented.

Another object of the present invention is to provide a slide opening/closing-type device, which can prevent a cover of a portable electronic device, which has been opened in one direction, from being opened in another direction.

Another object of the present invention is to provide a slide opening/closing-type device, which can implement a portable electronic apparatus, which can have an uncomplicated structure and can be opened/closed in both directions, that is, an up-down direction and in a right-left direction.

Another object of the present invention is to provide a slide opening/closing-type device, which can have an uncomplicated structure and can implement a portable electronic apparatus, which can be opened/closed in the first and second directions.

Another object of the present invention is to provide a slide opening/closing-type device, which allows an apparatus to be selectively opened in a first direction or a second direction in a state where a cover of the apparatus has been closed, and allows the apparatus to be changed from a state where it has been opened in the first direction to a state where it has been opened in a second direction or to be changed in an opposite manner.

Another object of the present invention is to provide a slide opening/closing-type device, which can repeatedly operate a circular movement while changing its state to a state where a cover has been closed, a state where the cover has been opened in a first direction, a state where the cover has been opened in a second direction, and a state where the cover has been closed, or a circular movement in the opposite direction.

### Technical Solution

According to an aspect of the present invention, there is provided a slide-type opening/closing device, which includes: a base member, on which first guide parts are installed; a first sliding member having first guided parts, which are movably engaged with the first guide parts, and second guide parts installed on the first sliding member in a direction different from a guiding direction of the first guide parts; and a second sliding member having second guided parts movably engaged with the second guide parts.

It is preferable that a first engaging part and a first engaged part are installed on the base member and the second sliding member, respectively in such a manner that the first engaging part and the first engaged part are engaged with each other so as to allow the first sliding member to slide along the first guide parts in a state where the second sliding member doesn't slide along the second guide parts, and so as to prevent the first sliding member from sliding along the first guide part in a state where the second sliding member has slid along the second guide parts.

The first engaging part may be a protuberance formed on the base member, and the first engaged part is a groove or a protuberance, which is formed on the second sliding member and has a gap allowing the first engaging part to pass through the gap in a state where the second sliding member doesn't slide along the second guide parts, or the first engaged part is a protuberance formed on the second sliding member, and the first engaging part is a groove or a protuberance, which is formed on the base member and has a gap allowing the first engaged part to pass through the gap in a state where the second sliding member doesn't slide along the second guide parts.

A second engaging part and a second engaged part may be installed on the base member and the second sliding member in such a manner that the second engaging part and the second engaged part are engaged with each other so as to allow the second sliding member to slide along the second guide parts in a state where the first sliding member doesn't slide along the first guide parts, and so as to prevent the second sliding member from sliding along the second guide parts in a state where the first sliding member has slid along the first guide parts.

The second engaging part may be a protuberance formed on the base member, and the second engaged part is a protuberance, which is formed on the second sliding member and has a gap allowing the second engaging part to pass through the gap in a state where the first sliding member doesn't slide along the first guide parts, or the second engaged part is a protuberance formed on the second sliding member, and the second engaging part is a groove or a protuberance, which is formed on the base member and has a gap allowing the second engaged part to pass through the gap in a state where the first sliding member doesn't slide along the first guide parts.

It is preferable that a limiting protuberance protruding upward is formed on the base member, a through-hole, which allows the limiting protuberance to pass via the through-hole and isn't interrupted from the limiting protuberance when the first sliding member slides along the first guide part, is formed on the first sliding member, and a path limiting part is formed on the second sliding member along a predetermined path so that the path limiting part is engaged with the limiting protuberance passed through the first sliding member so as to limit movement path of the second sliding member.

In this case, the path limiting part is formed along a closed path, and the closed path is one of a path obtained by combining liner paths, a path obtained by combining curve paths, and a path obtained by combining liner paths and curve paths.

It is preferable that the path limiting part includes a first path limiting part, which allow the second sliding member to be free from the limiting protuberance when the second sliding member slides along the second guide parts, and a second path limiting part, which allows the first sliding member to be free from the limiting protuberance when the first sliding member slides along the first guide parts.

A guide groove, which is arranged in a same direction of the first guide part, may be formed on the base member, a cable supporter, which may be supported by a torsion spring in a direction where the cable supporter escapes from the base member, may be movably installed on the guide groove, and a locking stepped part is formed on an bottom surface of the first sliding member, the locking stepped part holding the cable supporter in a closed state of the first sliding member and releases the cable supporter when the first sliding member is opened so that the cable supporter is moved due to elastic force of the torsion spring to cover a FPC cable escaping from the base member, and being locked in one portion of the cable supporter when the first sliding member returns to its original position so as to allow the cable supporter to return its original position.

It is preferable that each first guide part is formed in such a manner that a rail member is attached onto the base member, the rail member having a pair of guide paths, which are positioned in parallel with an vertical interval between them and are arranged in a left-right direction.

It is preferable that the second guide parts are shaped like each groove or each protuberance formed along both side surfaces of the first sliding member in an up-down direction, and the second guided parts are shaped like each protuberance or each groove formed along inner surfaces of downward protruding parts, which protrude downward along each edge of both sides of the second sliding member and are arranged outside of both side surfaces of the first sliding member.

As the case may be, each first guide part may be locked in the base member or a part connected with the base member and is folded before the first sliding member is opened through sliding along the first guide part, and in a state where the first sliding member has been opened through sliding along the first guide part, the first guide part may be released from the base member or the part connected with the base member so that the first guide part can be erected on a slant respective to the base member.

The first guide part and the first guided part may be installed through a slide hinge device installed between the base member and the first sliding member, and the sliding hinge device may include a hinge device, in which a connecting member, which has a locking part formed on the connecting member and is connected with the base member, and a rail member having the first guide parts, are foldably connected with each other, the hinge device receiving elastic force in a direction where the connecting member and the rail member are unfolded through a hinge spring, a guided plate, which is slidably assembled with the first guide parts, has a swing-triggering part formed on one end of the guided plate, and is installed on the first sliding member, and a swing member including a locking jaw, which is rotatably installed on the rail member and is locked in or released from the locking part according to a rotational angle, a swing-triggered part, which is locked in the swing-triggering part according to movement position of the guided plate and rotates so as to allow the locking jaw to be released from the locking part, or is released from the swing-triggering part and rotates in an opposite direction so as to allow the locking jaw to be locked in the locking part.

As the case may be, the first guide part and the first guided part may be installed through a slide hinge device installed between the base member and the first sliding member, and the slide hinge device may include a locking part and a hinge part, which are formed on the first sliding member, a rail member, which has first guide parts, is rotatably installed on the hinge part to be foldably connected with the first sliding member, and receives elastic force by a hinge spring in a direction where the rail member is unfolded respective to the first sliding member, a guided plate, which is slidably assembled with the first guide parts and has a swing-triggering part formed on one end of the guided plate, and a swing member including a locking jaw, which is rotatably installed on the rail member and is locked in or released from the locking part according to a rotational angle, and a swing-triggered part, which is locked in the swing-triggering part according to movement position of the guided plate and rotates so as to allow the locking jaw to be released from the locking part, or is released from the swing-triggering part and rotates in an opposite direction so as to allow the locking jaw to be locked in the locking part.

Each first guide part may be installed on the base member through a tilting part, which is tiltably installed on the base member, and can be bent upward or can be spread after being bent upward, so that the first sliding member can be bent respective to the base member with an acute angle in a state where the first sliding member has been opened through sliding along the first guide part. It is preferable that the tilting part includes a tilting link installation part, which is formed on the base member and has at least one stepped inner surface, a tilting plate installed near the tilting link installation part in such a manner that the tilting plate can rotate in a tilting direction, and a pair of tilting links having different lengths, each tilting link being rotatably installed on the tilting link installation part and being connected with the tilting plate.

The first guide part may be installed on the tilting part in such a manner that the first guide part can rotate about a rotational shaft member and allows the first sliding member to be bent with an acute angle respective to the base member in a state where the first sliding member has been opened through rotation.

It is preferable that a guide groove, which is arranged in a same direction of the first guide part, is formed on the base member, a cable supporter, which is supported by a torsion spring in a direction where the cable supporter escapes from the base member, is movably installed on the guide groove, and a locking stepped part is formed on an bottom surface of the first sliding member, the locking stepped part holding the cable supporter in a closed state of the first sliding member and releases the cable supporter when the first sliding member is opened so that the cable supporter is moved due to elastic force of the torsion spring to cover a FPC cable escaping from the base member, and being locked in one portion of the cable supporter when the first sliding member returns to its original position so as to allow the cable supporter to return its original position.

The first keys may be installed on an upper surface of the base member, which is exposed to the outside when the first sliding member is opened along the first guide part, and second keys may be installed on an upper surface of the first sliding member, which is exposed to an outside when the second sliding member is opened along the second guide part.

The first sliding member may have a length shorter than each length of the base member and the second sliding member and may be installed at a position where an upper surface of the first sliding member isn't exposed to an outside even though the first sliding member is opened through sliding along the first guide part, or the second sliding member is opened through sliding along the second guide part, and first keys used when the first sliding member is opened and second keys used when the second sliding member is opened are installed on an upper surface of the base member.

It is preferable that a first elastic device, which has one end rotatably connected with the base member and another end rotatably connected with the first sliding member so as to slide the first sliding member leftward or rightward respective to the base member according to position of the first sliding member, is installed between the base member and the first sliding member, and a second elastic device, which has one end rotatably connected with the first sliding member and another end rotatably connected with the second sliding member so as to slide the second sliding member upward and downward respective to the first sliding member according to position of the second sliding member, is installed between the first sliding member and the second sliding member.

As the case may be, the base member may be integrally formed on a lower body of a portable electronic apparatus, and the second sliding member is integrally formed on a cover of the portable electronic apparatus.

A portable electronic apparatus includes: a first body; a second body; and the slid-type opening/closing device according to the present invention, which is installed between the first body and the second body to allow the second body to be selectively opened respective to the first body in a first direction or in a second direction.

A potable electronic apparatus according to the present invention may includes a first body having a first guide part installed on the first body and a second body having a first sliding member, which has a first guided part, which is movably engaged with the first guide part, and a second guide part installed in a direction different from a direction of the first guide part, and a second guided part, which is movably engaged with the second guide part.

### Advantageous Effects

The slide opening/closing-type device and a portable electronic apparatus according to the present invention allow the user to selectively open/close a cover of the apparatus in one of an up-down direction and a left-right direction.

In a case where a guide part is installed at a certain angle, the cover of the apparatus can be also opened in a slanted direction as well as the up-down direction or the left-right direction.

The slide opening/closing-type device and a portable electronic apparatus according to the present invention has an uncomplicated structure and allows the user to selectively open the cover of the apparatus in one of both directions, that is, an up-down direction and an left-right direction, according to need.

In the slide opening/closing-type device and the portable electronic apparatus according to the present invention, when the cover of the apparatus is opened in the first direction, the cover isn't allowed to be opened in the second direction, or the cover is allowed to be opened/closed in the first direction as well as the second direction, or when the cover is opened in one of both directions, the cover isn't allowed to be opened in the other direction, but the cover is allowed to be opened in the opposite direction.

The slide-type opening/closing device and the portable electronic apparatus according to the present invention also allow the cover of the apparatus to be opened along a rectangular path in a case where there is no limitation in an opening manner.

As the case may be, the slide opening/closing-type device and the portable electronic apparatus according to the present invention allows the cover of the apparatus to be opened/closed along a curve path so that the user can have new feel different from feel caused when opening/closing the cover along a linear path.

Additionally, the slide-type opening/closing device and the portable electronic apparatus according to the present invention allow the opening/closing path of the cover of the apparatus to be variously designed according to the consumer's desire.

Moreover, according to the present invention, the apparatus can have various opening/closing paths or various opened/closed states, and when the apparatus, which has been opened in the first direction, is again opened in the second direction or when the apparatus is opened in an opposite manner, the cover of the apparatus can move in a diagonal direction allowing a shortest movement distance.

The apparatus can be selectively opened/closed in one of both directions, that is, an up-down direction and a left-right direction.

In the slide opening/closing-type device and the slide opening/closing-type electronic apparatus according to the present invention, since a locking jaw takes torque of a hinge spring while a guided plate moves along a first guide part, scratches and a large amount of frictional force, which are caused by the torque of the hinge spring, aren't generated between a rail member and the guided plate so that the guided plate can smoothly slides.

Accordingly, the slide opening/closing-type electronic apparatus according to the present invention has superior operational feel according to sliding and a long life span and has no operational troubles.

In addition, the slide hinge device and the slide opening/closing-type electronic apparatus according to the present invention contribute to improvement of quality of PDAs, cellular phones, portable game players, electronic notes, etc.

### BRIEF DESCRIPTION OF DRAWINGS

The foregoing and other objects, features and advantages of the present invention will become more apparent from the following detailed description when taken in conjunction with the accompanying drawings in which:

FIG. 1 is a perspective view of a portable electronic apparatus employing a slide-type opening/closing device according to the present invention, in which a state of a second elastic device positioned between a first sliding member and a second sliding member is shown;

FIG. 2 is an exploded perspective view of a portable electronic apparatus of FIG. 1;

FIG. 3 is an exploded perspective view of the portable electronic apparatus of FIG. 1, in which a state where the portable electronic apparatus has been reversed in a left-right direction through rotation is shown;

FIG. 4 is a perspective view showing a state where a second sliding member has been opened upward along a second guide part based on the state of FIG. 1;

FIG. 5 is a view showing the configuration between the base member and a first sliding member;

FIG. 6 is a view showing a state where a first sliding member, a second sliding member, and a second body are opened in a rightward direction together with each other, based on the state of FIG. 5;

FIG. 7 is an exploded perspective view showing another embodiment of a portable electronic apparatus using a slide-type opening/closing device according to the present invention;

FIG. 8 is an exploded perspective view showing a state where the portable electronic apparatus of FIG. 7 is reversed through rotation in a left-right direction;

FIG. 9 is a perspective view showing a state where a second body is opened upward in such a manner that a second sliding member is moved upward;

FIG. 10 is a perspective view showing a state where a second body is opened through sliding of a first sliding member is moved in a right direction;

FIG. 11 is an exploded perspective view showing another embodiment of a portable electronic apparatus using a slide-type opening/closing device according to the present invention;

FIG. 12 is an exploded perspective view showing the portable electronic apparatus of FIG. 11, in which the portable electronic apparatus is reversed in an up-down direction through rotation in a left-right direction;

FIG. 13 is a perspective view of a slide hinge device installed between a first sliding member and a second sliding member;

FIG. 14 is an exploded perspective view of the slide hinge device of FIG. 13;

FIG. 15 is an exploded perspective back view of the slide hinge device of FIG. 13;

FIG. 16 is a partially cut-off perspective view of the slide hinge device of FIG. 13, in which an assembled inner state of the slide hinge device is shown;

FIG. 17 is a partially cut-off perspective view of the slide hinge device, in which a guided plate has moved to be unfolded;

FIG. 18 is a partially cut-off perspective view of the slide hinge device, in which a rail member and a guided plate have been unfolded based on the state of FIG. 17;

FIG. 19 is a rear view of the slide hinge device of FIG. 16;

FIG. 20 is a rear view of the slide hinge device of FIG. 17;

FIG. 21 is a side view of the slide hinge device of FIG. 17, in which the slide hinge device has been unfolded;

FIG. 22 is an exploded perspective view of a slide- opening/closing-type electronic apparatus according to the present invention, in which a configuration between a first body and a first sliding member is shown;

FIG. 23 is an exploded perspective back view of the slide opening/closing -type electronic apparatus of FIG. 22;

FIG. 24 is a view showing a closed state of a slide opening/closing-type electronic apparatus according to the present invention;

FIG. 25 is a view showing a state where a second body has been moved along first guide parts;

FIG. 26 is a view showing a state where the second body has been erected on a slant after moving along the first guide parts;

FIG. 27 is a sectional view showing another embodiment of a structure where a swing member, a swing-triggering part, and a swing-triggered part are assembled;

FIG. 28 is an exploded perspective view showing another embodiment of a slide hinge device according to the present invention;

FIG. 29 is an exploded perspective view showing a slide opening/closing-type electronic apparatus according to another embodiment of the present invention;

FIG. 30 is an exploded perspective view of a portable electronic apparatus, in which a structure between a first body and a first sliding member according to another embodiment of the present invention is shown;

FIG. 31 is an exploded perspective back view of the portable electronic apparatus of FIG. 30;

FIG. 32 is a perspective rear view showing a state where a second body of the assembled portable electronic apparatus of FIG. 30 is tilted after sliding along the first guide parts;

FIG. 33 is a side view of FIG. 32;

FIG. 34 is an exploded perspective view showing a slide opening/closing-type electronic apparatus according to another embodiment of the present invention;

FIG. 35 is an exploded perspective back view of the slide opening/closing-type electronic apparatus of FIG. 34;

FIGS. 36 to 39 are plane views showing a state where the first body has been closed, a state where the first body has been opened in a second direction, a state where the opened state in the second direction is converted to an opened state in a first direction, and the state where the first body has been opened in the first direction, respectively;

FIG. 40 is an exploded perspective view showing a modified embodiment of FIGS. 34; and

FIGS. 41a to 41d are views showing modified embodiments of a path limiting part.

### BEST MODE FOR CARRYING OUT THE INVENTION

Hereinafter, preferred embodiments according to the present invention will be described in detail with reference to the accompanying drawings.

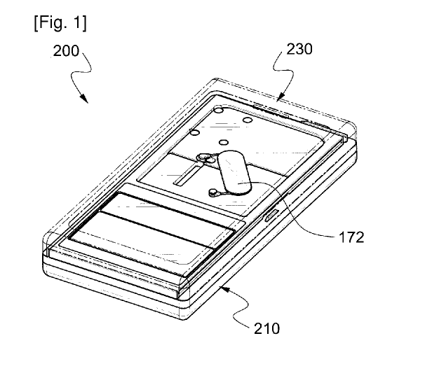

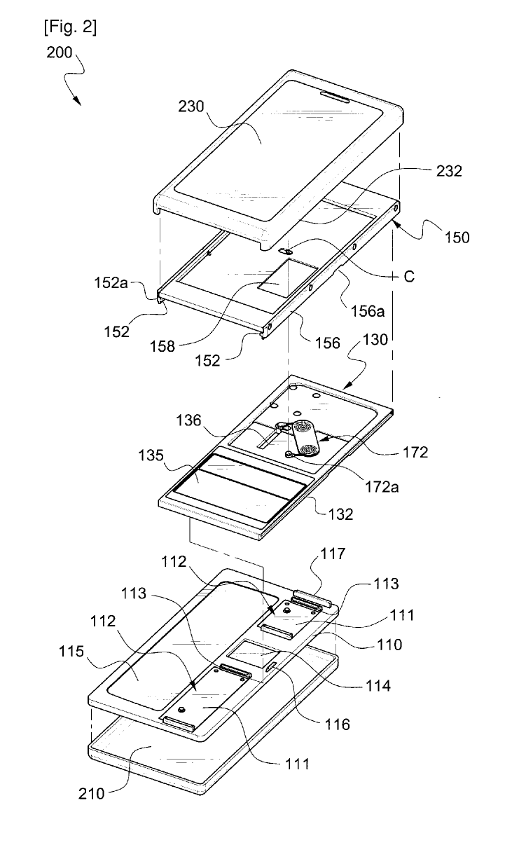

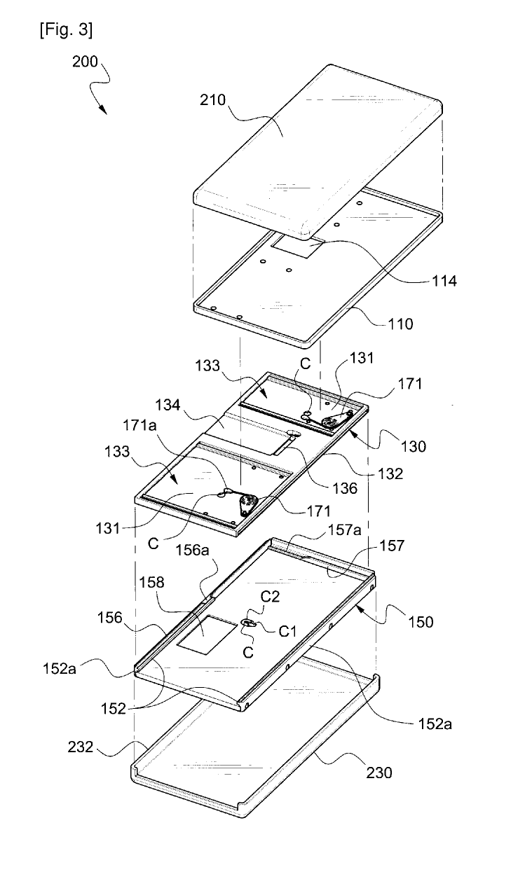

FIG. 1 is a perspective view of a portable electronic apparatus employing a slide-type opening/closing device according to the present invention, in which a state of a second elastic device positioned between a first sliding member and a second sliding member is shown, FIG. 2 is an exploded perspective view of the portable electronic apparatus of FIG. 1, and FIG. 3 is an exploded perspective view of the portable electronic apparatus of FIG. 1, in which a state where the portable electronic apparatus has been reversed in a left-right direction through rotation is shown.

The slide opening/closing-type portable electronic apparatus 200 includes a base member 110. First guide parts 111 are installed on the base member 110. It is preferable that the first guide parts is formed in such a manner that two rail members 112 having guide paths 113, which have each side groove opened to the inner side of each rail member and are formed in parallel, are installed at upper and lower sides of the base member in parallel. Each guide path 113 is desirably formed in a left-right direction. However, it is natural that the guide path 113 can be arranged in a direction inclined against the left-right direction according to need. The sizes of the two rail members 112 can be different from each other, and it is preferable that a through-hole, which allows a flexible cable, etc. for electrical signal transmission to pass via the through-hole, is formed between the two rail members 112.

Moreover, only one rail member with a large size can form a first guide part 111.

Also, the first guide parts 111 may be replaced with first guided parts 131, which will be described below, and may be installed by using a shaft method or other methods. If the first guide parts 111 can guide the first sliding member 130 to slide in a desired direction, there is no problem.

Although the first guide parts 111 have separate rail members 112 attached thereon as described above, it is also possible that the first guide parts 111 can be integrally formed on the base member 110.

As shown in FIG. 2, it is preferable that each first guide part 111 is installed on the right side or a part of the base member 110, and a first key seating part 115 for installation of the first keys is arranged on the left side of the base member. The first key installation part 115 is a part exposed to the outside when the first sliding member 130 has been opened to the right side along the first guide part 111. The first keys are keys allowing the user to be conveniently perform a game function, etc. of the portable electronic apparatus 200 while clasping the apparatus with both hands after positioning the portable electronic apparatus 200 in a transverse direction.

A first engaging part 116 with a protuberance-shape is formed on the upper surface of the base member 110. The first engaging part 116 isn't engaged with a first engaged part 156, which will be described below, so as to allow the first sliding member 130 to slide along the first guide part 111 in a state where the second sliding member 150 doesn't move along a second guide part 132, which will be described below. Meanwhile, the first engaging part 116 is engaged with the first engaged part 156 so as to prevent the first sliding member 130 from sliding along the first guide part 111 in a state where the second sliding member 150 has moved along the second guide part 132. It is preferred that the first engaging part 116 is installed on the right edge of the base member 110. However, the location of the first engaging part 116 may be changed in consideration of the installation position of other components in a product designing process.

Referring to FIG. 3, the first engaged part 156 is installed on the edge of the second sliding member 150. A gap 156a, which allows the first engaging part 116 to pass through the gap in the left-right direction, is formed on one portion of the first engaged part 156. In this embodiment, the first engaged part 156 and a rim 232 of one side of the second body 230 of the portable electronic apparatus 200, which is attached to the bottom surface of the base member 110 or is integrally formed on the base member 110, are arranged with an interval so as to allow the first engaging part 116 to move in a up-down direction. Also, the first engaged part 156 may have a groove-shape.

As the case may be, the first engaging part 116 and the first engaged part 156 may be installed in such a manner that their locations or their shapes are replaced with each other.

The second engaging part 117 is installed on the upper surface of the base member 110. This second engaging part 117 is installed in such a manner that it has been engaged in a second engaged part 157, which will be described below so as to allow the second sliding member 150 to slide along the second guide part 132 in a state where the first sliding member 130 doesn't slide along the first guide part 111, and so as to prevent the second sliding member 150 from sliding along the second guide part 132 in a state where the first sliding member 130 has slid along the first guide part 111. The second engaging part 117 may be installed on the right side of the upper part of the base member 110 while having a protuberance-shape. However, this configuration of the second engaging part can be changed in a product designing process, and the shape of the second engaging part 117 can be changed into a groove-shape.

With reference to FIG. 3, the second engaged part 157 corresponding to the second engaging part 117 is formed on the upper part of the second sliding member 150 and has a protuberance-shape with a gap 157a allowing the second engaging part 117 to pass through the gap in an up-down direction.

The first body 210 of the portable electronic apparatus 200 is attached onto the bottom surface of the base member 110 or is formed integrally with the base member. The first body 210 is a part, on which a circuit board for processing various signals of the portable electronic apparatus 200, a battery, etc. are generally installed.

As the case may be, the base member 110 can be formed integrally with the first body 210.

The first sliding member 130 is assembled with the base member 110. The first guided parts 131 are installed on the bottom surface of the first sliding member 130 in such a manner that the first guided parts can move along each first guide part 111. It is preferable that the first guided parts 131 are formed in such a manner that the guided plates 133, which can be assembled with the first guide parts 111 and move, are attached onto the bottom surface of the first sliding member 130. Similarly to the rail members 112, two guided plates 133 are installed on the upper and lower parts of the first sliding member 130 with an interval. Also, it is possible to install one guided plate 133 with a large size according to the configuration type of the first guide parts 111, and it is possible to install the guided plate with a slant against the left-right direction. Also, each first guided part 131 can be formed integrally with the bottom surface of the first sliding member 130, and the shape of the first guided part 131 can be replaced with the first guide part 111. Also, the first guided part 131 may be configured by other methods, such as a shaft method, according the configuration type of the first guide parts 111.

The second guide parts 132 are formed on the first sliding member 130. The second guide parts 132 with a groove-shape are formed on both side surfaces of the first sliding member 130 so as to guide the second sliding member 150 to slide in the up-down direction. As the case may be, the second guide parts 132 can have protuberance-shapes protruding out of both surfaces of the first sliding member 130, respectively. Also, although it is preferred that the second guide parts 132 are formed on both side surfaces of the first sliding member 130, this is not necessary. Therefore, the second guide parts can be formed on the upper surface of the first sliding member 130.

When the first sliding member 130 is opened and closed along the first guide part 111 in the left-right direction, it is necessary that the first engaging part 116 doesn't interfere with the sliding of first sliding member within an opening/closing range. Therefore, in a case where the bottom surface of the first sliding member 130 is positioned lower than the upper end of the first engaging part 116, it is required that a recess 134 is formed on the part of the first sliding member, which corresponds to the first engaging part 116, so as to prevent the first sliding member from being engaged in the first engaging part 116. Of course, in a case where the bottom surface of the first sliding member 130 is positioned higher than the upper end of the first engaging part 116, there is no need to form the recess on the first sliding member.

A second key seating part 135, on which the second keys to be used when the second sliding member 150 is opened are installed, is included in one side of the upper surface of the first sliding member 134, which is exposed to the outside when the second sliding member 150 is opened along the second guide part 132. It is preferable that a through-hole 136 allowing a flexible cable to pass via the through-hole is formed on the first sliding member 130. Although it is possible to install a flexible cable through a gap formed on the edge of each component in a case where there is no through-hole 136, there are various disadvantages in that installation is very difficult, and a large amount of material is required.

First elastic bodies 171 are installed between the first sliding member 130 and the base member 110. It is preferred that each first elastic body 171 has one end rotatably connected with the base member 110 and the other end rotatably connected with the first sliding member 130. Of course, as the case may be, the first elastic body 171 and a second elastic body 172, which will be described below, can have both ends fixed or can have one fixed end and the other end, which is rotatably connected. Furthermore, in a certain case, it is also possible that the slide opening/closing-type device 100 and the portable electronic apparatus 200 can be configured without the first elastic bodies 171 and the second elastic body 172. The first and second elastic bodies 171 and 172 preferably include a torsion spring having a wound part with a spiral shape and an extending arm extending from the wound part to the outside, and an spring receiving member, which receives the wound part and allows an inner end of the wound part to be fixed in one portion of the spring receiving member. However, it is also possible to use a spring and a spring device with a different type.

It is illustrated that the second sliding member 150 is positioned on the first sliding member 130. The second sliding member 150 includes the second guided parts 152, which are assembled therewith in such a manner that the second guided parts 152 can move along the second guide parts 132. The second guided parts 152 have a protuberance-shape formed along an inner surface of each downward protruding part 152a, which protrudes downward along both edges of the second sliding member 150 to be arranged outside of both side surfaces of the first sliding member 130. In a case where the second guide parts 132 have a protuberance-shape, the second guided parts 152 may have a groove-shape.

As described above, through the cooperative operation between the second sliding member 150 and the first engaging part 116 or the cooperative operation between the second sliding member 150 and the second engaging part 117, sliding of the second sliding member 150 along the second guide part 132 is prevented when the first sliding member 130 slides along the first guide part 111, and the sliding of the first sliding member 130 along the first guide part 111 is prevented when the second sliding member 150 slides along the second guide part 132.

A through-hole 158 for allowing a flexible cable, etc. to pass therethrough is formed on the second sliding member 150. The second body 230 of the portable electronic apparatus 200 is assembled with an upper surface of the second sliding member 150. As the case may be, the second sliding member 150 may be formed integrally with the second body 230.

Also, the second elastic device 172 is installed between the first sliding member 130 and the second sliding member 150. It is preferable that the second elastic device 172 has one end rotatably connected with the first sliding member 130 and the other end rotatably connected with the second sliding member 150. Of course, as the case may be, it is possible that the second elastic device 172 has both fixed ends or has one fixed end and the other end, which is rotatably connected.

Typically, a displayer is installed on the second body 230.

Hinges 171a and 171b are installed at both ends of each first elastic device 171 and the second elastic device 172 so as to rotatably support them, thereby allowing them to rotate together with the base member 110, the first sliding member 130, and the second sliding member 150, etc. It is preferred that the hinges 171a and 172a are integrally formed at ends of the first elastic device 171 and the second elastic device 172, respectively, through insert injection molding. It is preferred that an elastic device connection part C is formed on the base member 110, the first sliding member 130, and the second sliding member 150 so as to allow the hinges 171a and 172a to be easily connected. The elastic device connecting part C has an expanding part C1, which has a large area so as to allow the hinges 171a and 172a to be inserted therein, and a hinge insertion mounting part C2, which has an narrow inlet so as to allow the hinges 171a and 172a inserted into the expanding part C1 to be inserted therein and rotatably supported by the hinge insertion mounting part. The hinge insertion mounting part C2 protrudes out of one side of the elastic device connecting part C through pressure and is positioned in a direction where there is no concern that the hinge 171a and 172a escape therefrom in consideration of an operational direction of elastic force within the operation range of the first elastic device 171 and the second elastic device 172.

In a case where the elastic device connection part C is formed as described above, the first and second elastic devices 171 and 172 are easily installed.

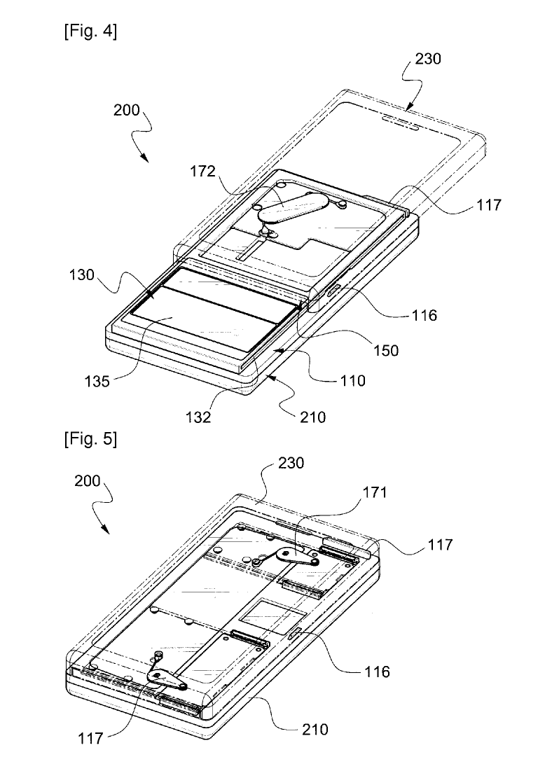

FIG. 4 is a perspective view showing a state where the second sliding member has been opened upward along a second guide part based on the state of FIG. 1.

When the second body 230 is moved upward based on the state of FIG. 1, the second sliding member 150 and the second body 230 is opened upward along the second guide part 132. At this time, the second elastic device 172 is rotated about a portion connected with the first sliding member 130 in a counterclockwise direction and applies an elastic force in a direction where the elastic force interrupts upward movement of the second sliding member 150 and the first body, that is, in a lower direction within a predetermined section. After the time point when the end of the second elastic device 172, which is connected with the second sliding member 150, passes the other end of the second elastic device 172 connected with the first sliding member 130, the second elastic device 172 applies an elastic force upward to the second sliding member 150 and the second body 230. In this state, although outer force is removed, the second sliding member 150 and the second body 230 are opened upward due to elastic force of the second elastic device 172.

A procedure of closing the second body 230 as shown in FIG. 1 based on the state where the second body 230 has been opened upward as shown in FIG. 4 is performed as the opposite procedure of the opening procedure.

As such, in a case where the second body 230 is opened upward, when the second sliding member 150 slides upward along the second guide part 132, the first engaging part 116 formed on the upper surface of the base member 110 shown in FIG. 2 is positioned outside of the first engaged part 156 shown in FIGS. 2 and 3, so that the first sliding member 130 cannot slide along the first guide part 111 in a right direction. However, when the second sliding member 150 returns to the closed state shown in FIG. 1, the first engaging part 116 is aligned with the gap 156a. Therefore, even though the first sliding member 130 slides rightward, because the first engaging pat 116 pass through the gap 156a to the right side, the first engaging part 116 doesn't interfere the opening/closing operation of the second body 230, etc. in the left-right direction. This is the same in a case of the closing procedure of the second body 230.

The non-described reference S shows a screw for assembling components.

FIG. 5 is a view showing the configuration between the base member and the first sliding member, and FIG. 6 is a view showing a state where the first sliding member, the second sliding member, and the second body are opened in a right direction together with each other, based on the state of FIG. 5.

In the state of FIG. 5, when the second body 230 is pushed in the right direction, the first sliding member 130 slides along the first guide part 111 in the right direction. Accordingly, the second sliding member 150 and the second body 230, which are positioned on the first sliding member 130, are moved rightward together with the first sliding member.

At this time, while two first elastic devices 171 are rotated about each portion thereof connected with the base member 110 in a clockwise or counterclockwise direction, respectively, they apply elastic force leftward to the first sliding member 130 within a predetermined section. Then, from when each portion of the first elastic devices, which is connected with the first sliding member 130, passes a lower part of the portion connected with the base member 110, the first elastic devices applies an elastic force rightward to the first sliding member 130. In this case, even though the outer force is removed from the second body 230, the first sliding member 130, and the second sliding member 150, and the second body 230 are opened in the right direction by the elastic force of the first elastic devices 171 as shown in FIG. 6. The procedure of closing the first sliding member 130, etc. is performed as the opposite procedure of the opening procedure.

Meanwhile, in the state of FIG. 5, since the second engaging part 117 is aligned with the gap 157a formed at one portion of the second engaged part 157 of the second sliding member 150, the second engaging part 117 allows the second sliding member 150 to be opened upward as shown in FIG. 4. However, after the first sliding member 130 starts to slide rightward along the first guide part 111, the second engaging part 117 shown in FIG. 2 is inserted into an upper part of the second engaged part 157, which is formed on an upper end of the second sliding member 150 as shown in FIG. 3. As a result, the second sliding member 150 cannot slide upward.

When the second sliding member 150 tries to slide upward, the second engaged part 157 is engaged with the second engaging part 117 so that the second sliding member 150 and the second body 230 cannot move upward.

The non-described sign S shows a screw for assembling components.

### MODE FOR THE INVENTION

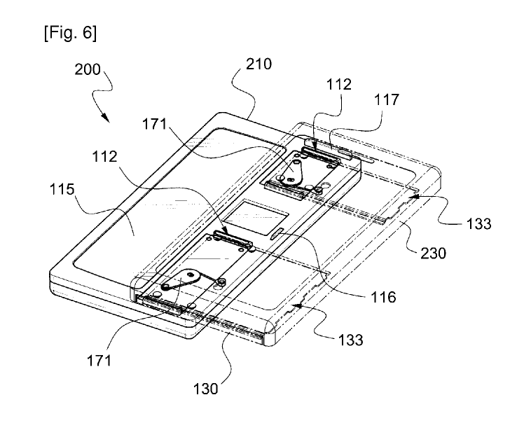

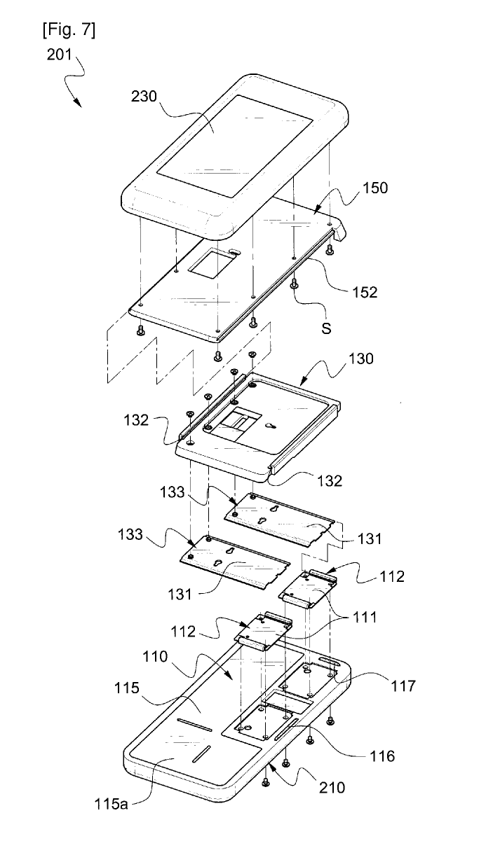

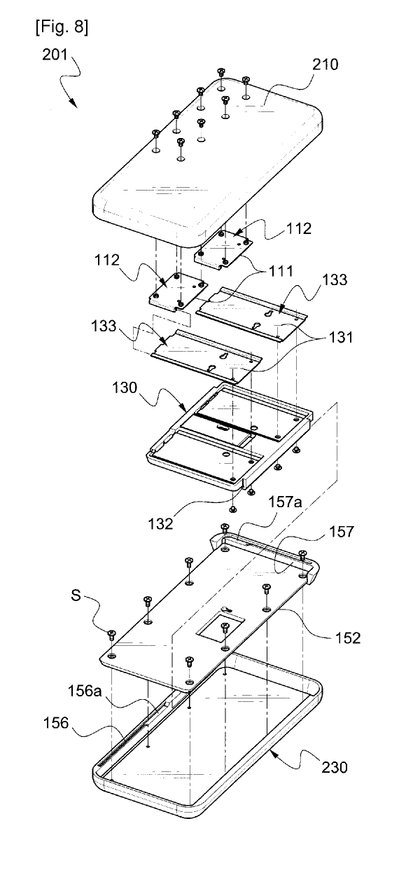

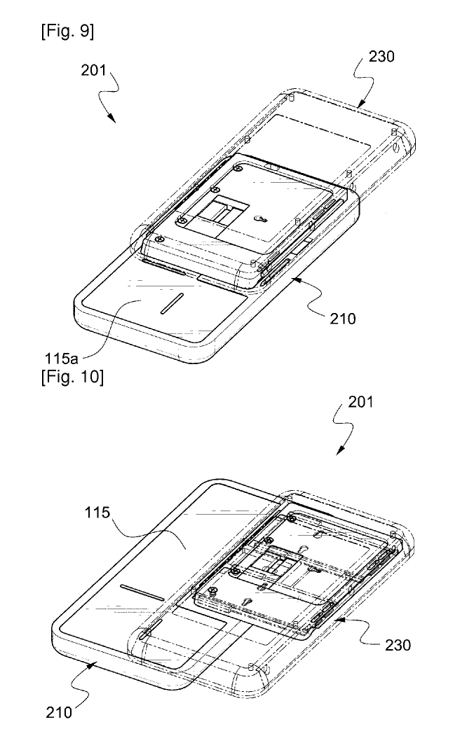

FIG. 7 is an exploded perspective view showing another embodiment of a portable electronic apparatus using a slide-type opening/closing device according to the present invention, and FIG. 8 is an exploded perspective view showing a state where the portable electronic apparatus of FIG. 7 is reversed through rotation in a left-right direction. FIG. 9 is a perspective view showing a state where a second body is opened upward in such a manner that a second sliding member is pushed upward, and FIG. 10 is a perspective view showing a state where the second body is opened through sliding of a first sliding member in a right direction.

In comparison with the above described embodiment, the embodiment shown in FIGS. 7 and 8 has a difference in that two rail members 112 included in first guide parts 111 are arranged with a narrow interval, and the first sliding member 130 has a short length so that a first key seating part 115 and a second installation part 115a are installed on a base member 110. In more detail, FIG. 9 shows a state where the second body 230 assembled with the second sliding member 150 is opened upward as each second guided part 152 of the second sliding member 150 is moved upward along each second guide parts 132 of the first sliding member 130. At this time, the second key seating part 115a arranged on the upper surface of the lower side of the base member 110 is exposed to the outside.

The non-described sign S shows a screw for assembling components.

FIG. 10 shows the state where the second body 230 has been opened rightward after the first guided parts 131 of the first sliding member 130 move rightward along each first guide part 111 of the base member 110. At this time, the second sliding member 150 and the second body 230, which are installed on the first sliding member 130, move together with the first sliding member 130. In the state of FIG. 10, the first key seating part 115 installed on an upper surface of the left part of the base member 110 is exposed to the outside. At this time, the first key seating part 115 and the second installation part 115a may be overlapped with each other on a partial area thereof.

That is, differently from the above described embodiment, in the slide opening/closing-type portable electronic apparatus 201, the first key seating part 115 and the second key seating part 115a are arranged on the upper surface of the base member 110.

Also, differently from the above described embodiment, in this embodiment, the based member 110 is integrally assembled with the first body 210, the second guide parts 132 have a groove-shape opened to each inner side of both edges protruding upward from the first sliding member 130, and the second guided parts 152, which are formed along both edges of the second sliding member 150, have a protuberance-shape extending to the outside.

The first engaging part 116, the second engaging part 117, and the second engaged part 157 are the same as those of the above described embodiment. Differently from the above described embodiment, the first engaged part 156 is formed on the first body 230. Of course, as the case may be, the first engaged part 156 may be installed on the second sliding member 150.

The remaining configurations except for these are the same as those of the above described embodiment.

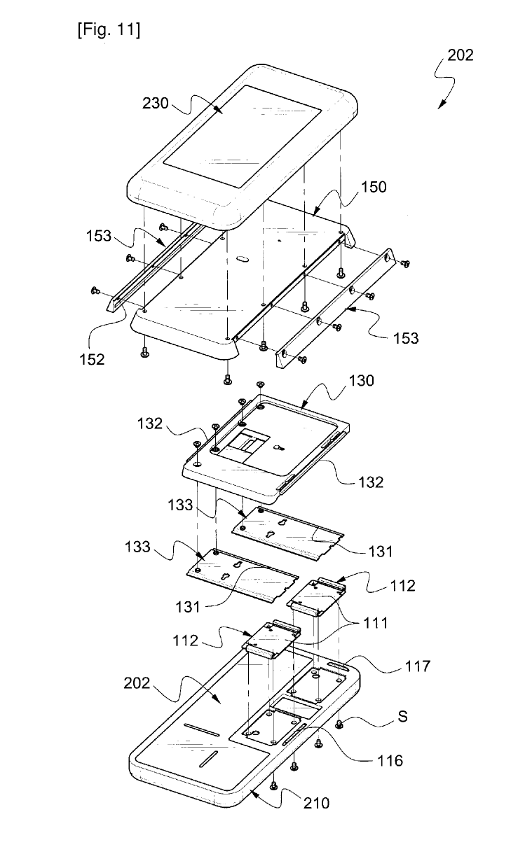

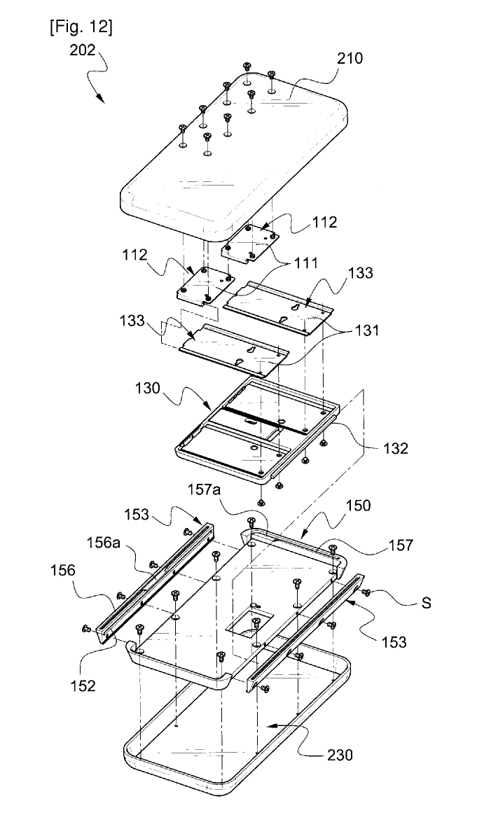

FIG. 11 is an exploded perspective view showing another embodiment of a portable electronic apparatus employing a slide opening/closing-type device according to the present invention, and FIG. 12 is an exploded perspective view showing the portable electronic apparatus of FIG. 11, in which the portable electronic apparatus is reversed in an up-down direction through rotation in a left-right direction.

In the slide-type opening/closing portable electronic apparatus 202 according to an embodiment shown in FIGS. 11 and 12, differently from the embodiment shown in FIGS. 7 and 8, the second guide parts 132 have protuberance-shapes protruding out of both surfaces of the first sliding member 130, respectively. Also, guide members 153, on which each second guided part 152 with a protuberance-shape opened to the inner side of the second sliding member, are attached onto both slide surfaces of the second sliding member 150. In addition, differently from the embodiment of FIGS. 7 and 8, the first locked part 156 with a groove-shape is formed on the guide members 153, which is attached to one side of the second sliding member. The remaining configurations are the same as those of the embodiment shown in FIGS. 7 and 8.

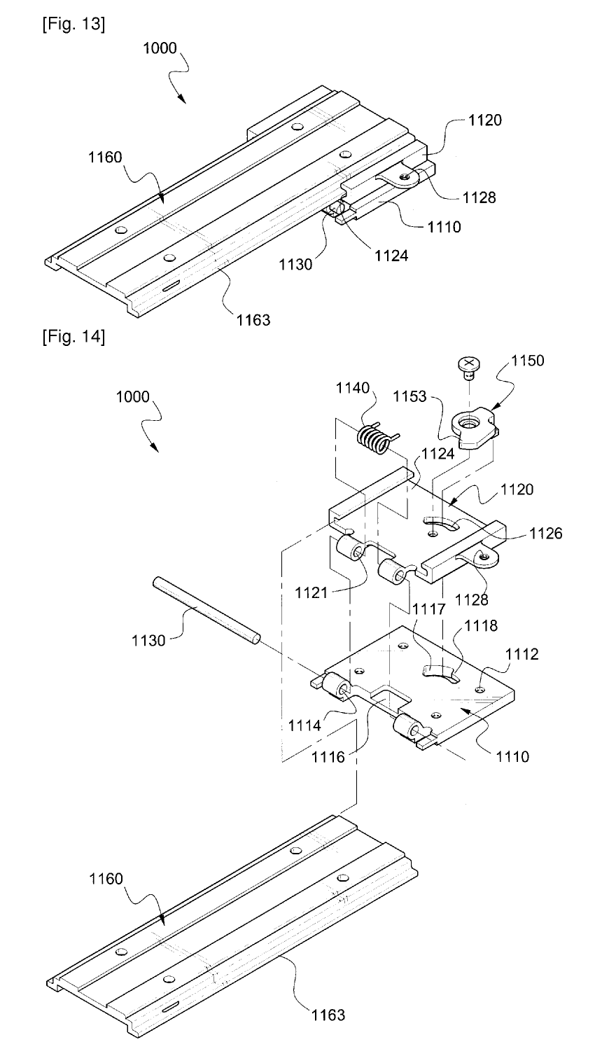

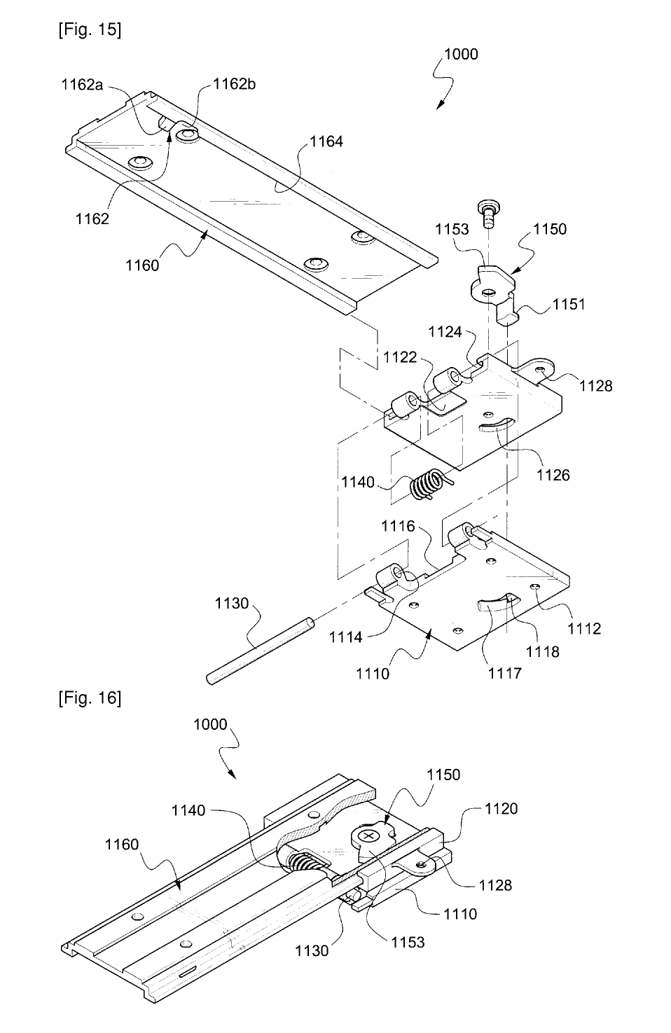

FIG. 13 is a perspective view of a slide hinge device installed between a first sliding member and a second sliding member, FIG. 14 is an exploded perspective view of the slide hinge device of FIG. 13, and FIG. 15 is an exploded perspective back view of the slide hinge device of FIG. 13.

In FIGS. 13 to 15, the slide hinge device 1000 according to the present invention is described. The slide hinge device 1000 is installed between the first sliding member and the based member or between the first body and the first sliding member, which have been described through FIGS. 1 to 12, so as to allow the first sliding member, the second sliding member, and the second body to be erected on a slant. The slide hinge device is a part corresponding to the rail member 112 and the guided plates 133.

As shown, the slide hinge device 1000 includes a connecting member 1110. The connecting member 1110 is connected with a first body or a base member of a slide-type opening/closing device, such as a PDA, a cellular phone, etc., and includes a plurality of assembling holes 1112. The connecting member 1110 has the first hinge holes 1114, with which a hinge shaft 1130 can be assembled, formed on one end of the connecting member in such a manner that they are positioned at both sides with an interval. A recess 1116, which allows one end of a hinge spring 1140 to be locked therein, is formed on an upper surface of the central part between the first hinge holes. The first through-hole 1117 and the locking part 1118 are formed near the other end of the connecting member 1110. The first through-hole 1117 allows a part of a swing member 1150, which will be describe below, to pass via the through-hole and allows it to rotate within a predetermined range. The locking part 1118 allows a locking jaw 1151 of the rotated swing member 1150 to be locked therein so as to maintain a state where the connecting member 1110 and the rail member 1120 have been folded.

The slide hinge device 1000 includes the rail member 1120. The rail member 1120 has second hinge holes 1121, into which the hinge shaft 1130 can be inserted, formed on one end of the rail member 1120 in such a manner that they are positioned at both sides of the end with an interval. The rail member 1120 is foldably connected with the connecting member 1110 through the hinge shaft 1130, and the rail member 1120 has a recess 1122, in which the other end of the hinge spring 1140 is locked, formed on the bottom surface of the central part between the second hinge holes 1121. A first guide part 1124 is formed on the rail member 1120. The first guide part 1124 is shaped like a T-shaped recess. It can be easily understood that shape of the first guide part 1124 can be variously changed. As the case may be, the shape of the first guide part 1124 can be replaced with the shape of a part to be guided by the first guide part 1124. A second through-hole 1126 is formed near the other end of the rail member 1120, which is positioned opposite to the second hinge holes 1121. The second through-hole 1126 allows a part of the swing member 1150, which will be described below, to pass via the through-hole and allows the swing member 1150 to rotate within a predetermined range. An elastic device connecting hole 1128 is formed on the edge of one side of the rail member 1120. The elastic device connecting hole 1128 allows one end of the elastic device, which provides a driving force to the body of the device, to be connected with the rail member.

The slide hinge device 1000 includes the hinge shaft 1130 and the hinge spring 1140. The hinge shaft 1130 is inserted into the first hinge holes 1114 and the second hinge holes 1121 so as to allow the connecting member 1110 and the rail member 1120 to be folded or unfolded about the hinge shaft 1130.

The hinge spring 1140 is assembled with the hinge shaft 1130 so that one end of the hinge spring is locked in the recess 1116 of the connecting member 1110 and the other end of the hinge spring is locked in the recess 1122 of the rail member 1120. Therefore, the hinge spring applies torque in a direction where the connecting member 1110 and the rail member 1120 are unfolded.

An assembly where the connecting member 1110, the rail member 1120, and the hinge shaft 1130, which have been described above, are assembled with each other functions as a hinge device.

The slide hinge device 1000 according to the present invention includes the swing member 1150. The swing member 1150 is installed on the rail member 1120 and can rotate about a rotational axis perpendicular to a surface of the rail member 1120. The swing member 1150 includes the locking jaw 1151, which passes through the second through-hole 1126 to be inserted into the first through-hole 1117 and has one bent end to be locked in the locking part 1118 or released therefrom according to rotational angle. The swing member 1150 also includes a swing-triggered part 1153, which is locked in a swing-triggering part 1162 according to the movement position of a guided plate 1160 and is rotated, thereby releasing the state where the locking jaw 1151 has been locked in the locking part 1118, or is released from the swing-triggering part 1162 and is rotated in the opposite direction, thereby allowing the locking jaw 1151 to be locked in the locking part 1118. The slide hinge device 1000 according to the present invention includes the guided plate 1160. The guided plate 1160 includes a first guided part 1163 and is assembled with a first guide part 1124 of the rail member 1120 to slide. The guided plate is a part connected with the second body of the slide-type opening/closing electronic device. The guided plate 1160 has side walls 1164 along the edges of both sides of the bottom surface thereof, and each end of the side wall extends to the outside. Therefore, when the guided plate 1160 is assembled with the first guide part 1124 of the rail member 1120, it is preferable that empty space is formed between the guided plate and the bottom surface of the rail member 1120. As shown, the swing-triggering part 1162 is formed on a side wall of one end of the guided plate 1160. The swing-triggering part 1162 allows the swing member 1150 to rotate at a position where the swing member 1150 makes contact with the swing-triggering part 1162 in such a manner that the swing-triggered part 1153 of the swing member 1150 is triggered by the swing-triggering part 1162.

In a state where the above described components are assembled with each other as shown in FIG. 13, when the swing-triggered part 1153 is locked in the swing-triggering part 1162 and rotates as one end of the guided plate 1160 approaches the rail member 1120, the swing member 1150 allows a state where the locking jaw 1151 has been locked in the locking part 1118 to be released so that the rail member 1120 is unfolded from the connecting member 1110 at an unfolding angle. Meanwhile, when the guided plate 1160 at the unfolding angle is moved due to outer force after the rail member 1120 has been unfolded on the connecting member 1110, the swing-triggered part 1153 rotates in the opposite direction while escaping from the swing-triggering part 1162 so as to allow the locking jaw 1151 to be locked in the locking part 1118 at a locking angle so that the rail member 1120 is folded on the connecting member 1110. Therefore, the guided plate 1160 can slide along the first guide part 1124 without the effects of torque being applied by the hinge spring 1140.

Herein, the swing-triggering part 1162 has a protuberance 1162a protruding out of the side surface thereof and a groove 1162b so that the swing member 1150 can rotate in a clockwise direction or in a counterclockwise direction. However, as the case may be, in a case where a spring is added so as to apply force to the swing member 1150 in one rotational direction, the swing-triggered part 1153 can have a short length, and the swing-triggering part 1162 can include only protuberance 1162a.

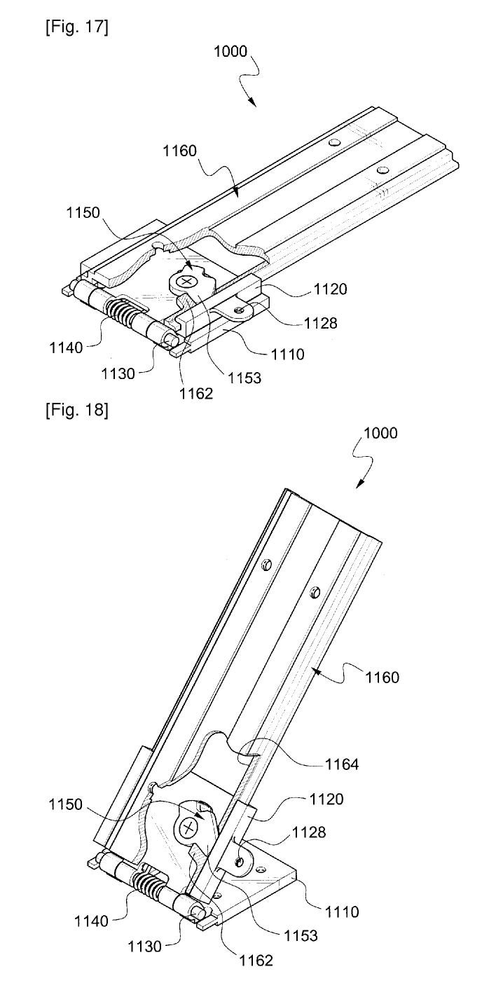

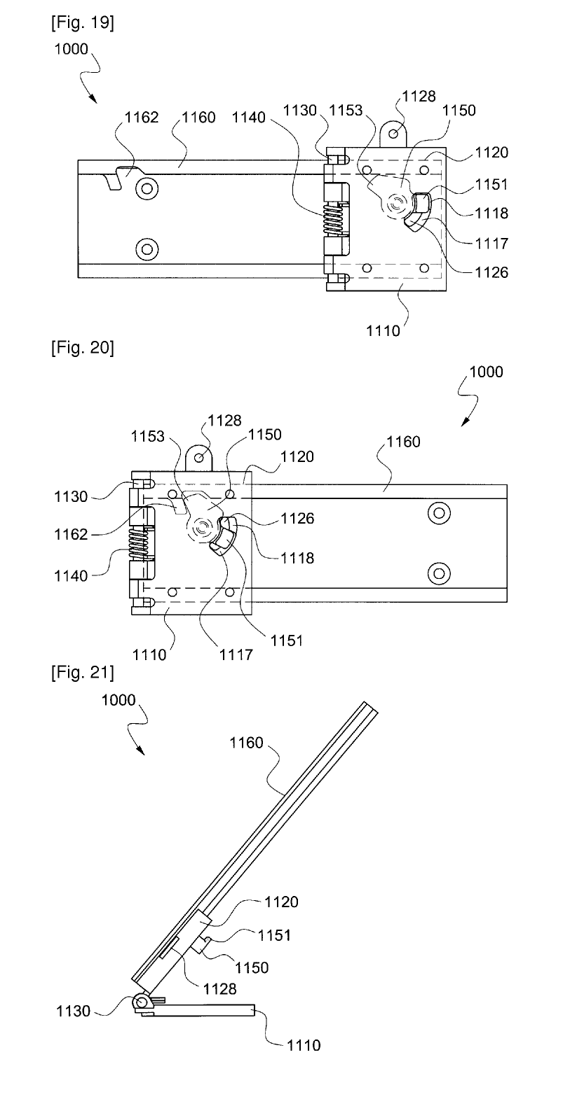

FIG. 16 is a partially cut-off perspective view of the slide hinge device of FIG. 13, in which an assembled inner state of the slide hinge device is shown, FIG. 17 is a partially cut-off perspective view of the slide hinge device, in which the guided plate has moved to be unfolded, and FIG. 18 is a partially cut-off perspective view of the slide hinge device, in which a rail member and a guided plate have been unfolded based on the state of the FIG. 17. Also, FIG. 19 is a rear view of the slide hinge device of FIG. 16, FIG. 20 is a rear view of the slide hinge device of FIG. 17, and FIG. 21 is a side view of the slide hinge device of FIG. 17, in which the slide hinge device has been unfolded.

FIGS. 16 and 19 show the folded state of the slide hinge device. One end of the guided plate 1160 is assembled with the rail member 1120. At this state, the swing-triggered part 1153 of the swing member 1150 makes contact with the side wall 1164 of the guided plate 1160 and has rotated in one direction. Accordingly, the locking jaw 1151 of the swing member 1150 is locked in the locking part 1118 of the connecting member 1110.

When the guided plate 1160 is moved so that the other end of the guided plate 1160 reaches the rail member 1120 as shown in FIGS. 17 and 20, the swing-triggered part 1153 of the swing member 1150 is locked in the swing-triggering part 1162 and is rotated. Accordingly, the locked jaw 1151 of the swing member 1150 rotates in a direction where the locking jaw escapes from the locking part 1118 of the connecting member 1110.

When the swing-triggered part 1153 of the swing member 1150 is locked in the swing-triggering part 1162 and is completely rotated in a clockwise direction, the locking jaw 1151 of the swing member 1150 completely escapes from the locking part 1118 of the connecting member 1110. Accordingly, as shown in FIGS. 18 and 21, in a case of there is no external force, the connecting member 1110 and the rail member 1120 are unfolded due to the force of the hinge spring 1140, and the guided plate 1160 together with the rail member 1120 is unfolded from the connecting member 1110.

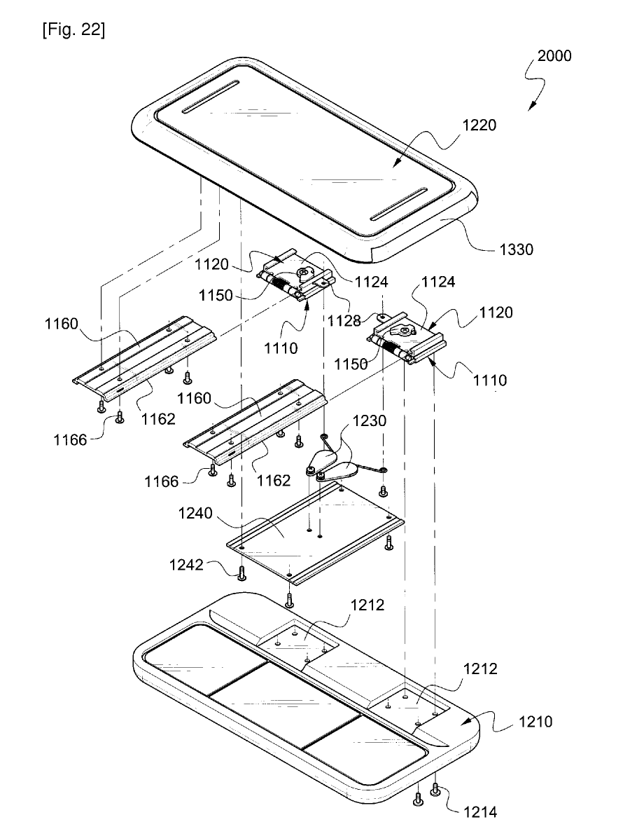

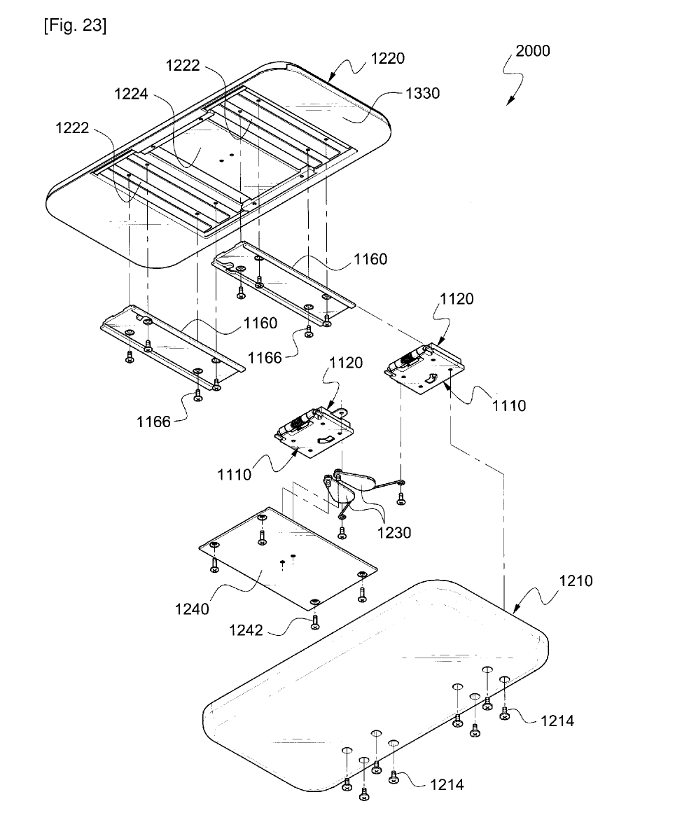

FIG. 22 is an exploded perspective view of the slide opening/closing-type electronic apparatus according to the present invention, in which a configuration between the first body and the first sliding member is shown, and FIG. 23 is an exploded perspective view of the slide-type opening/closing electronic device of FIG. 22, in which the device is shown in view of bottom surface.

As shown in FIGS. 22 and 23, the slide opening/closing-type electronic apparatus 2000 includes a first body 1210. The first body 1210 corresponds to a main part of a slide opening/closing-type electronic apparatus, such as a PDA, a cellular phone, etc., and input keys and buttons are typically installed on the first body. Connecting recesses 1212 for connection of connecting members 1110 are formed on the first body 1210 with an interval. The connecting members 1110 are assembled in the connecting recesses 1212 through screws, etc.

The slide opening/closing-type electronic apparatus 2000 according to the present invention includes a second body 1220. The second body 1220 is a part, on which a displayer of the sliding opening/closing-type electronic apparatus, such as a PDA, a cellular phone, etc. is installed. A second sliding member is attached onto the bottom surface of the second body or is formed integrally with the second body, and a first sliding member 1330 is assembled with the lower part of the second body as shown in FIG. 23. The mounting grooves 1222 for fixing the guided plate 1160 are formed on the bottom surface of the first sliding member 1330 with an interval, and a recess 1224 for installation of the elastic device 1230 is formed between the mounting grooves. Each guided plate 1160 is mounted on each mount groove 1222 through assembling members, such as screws 166.

Each guided plate 1160 assembled with the second body 1220 is slidably assembled with the first guide part 1124 of the rail member 1120. As the case may be, the guided plate 1160 may be integrally formed on the bottom surface of the second body 1220.

Preferably, the slide opening/closing-type electronic apparatus 2000 according to the present invention includes elastic devices 1230. Each elastic device 1230 is operated to slide the second body 1220 in a first direction or in a second direction according to movement position of the guided plate 1160. One end of the elastic device 1230 is rotatably connected with the elastic device connecting hole 1128 formed on the edge of the rail member 1120, and the other end of the elastic device 1230 is rotatably connected with the bottom surface of the second body 1220, preferably, through a supporting plate 1240, which will be described below. The supporting plate 1240 is arranged on the bottom surface of the recess 1224 so as to support the other end of each elastic device 1230 and supports the bottom surface of the central portion of the elastic device 1230 so as to prevent the central portion from protruding downward.

Although it is described in the embodiment that a pair of slide hinge devices are installed, as the case may be, one or more than two slide hinge devices may be installed.

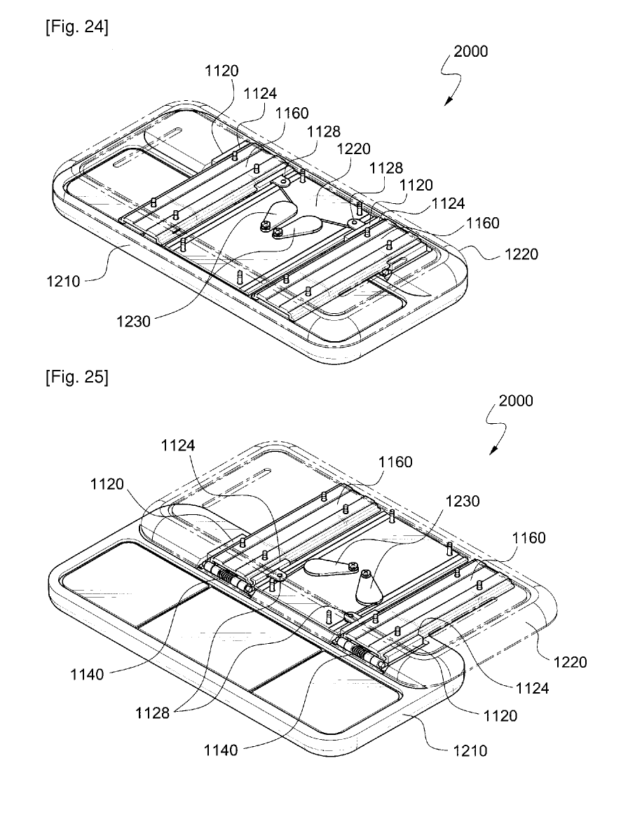

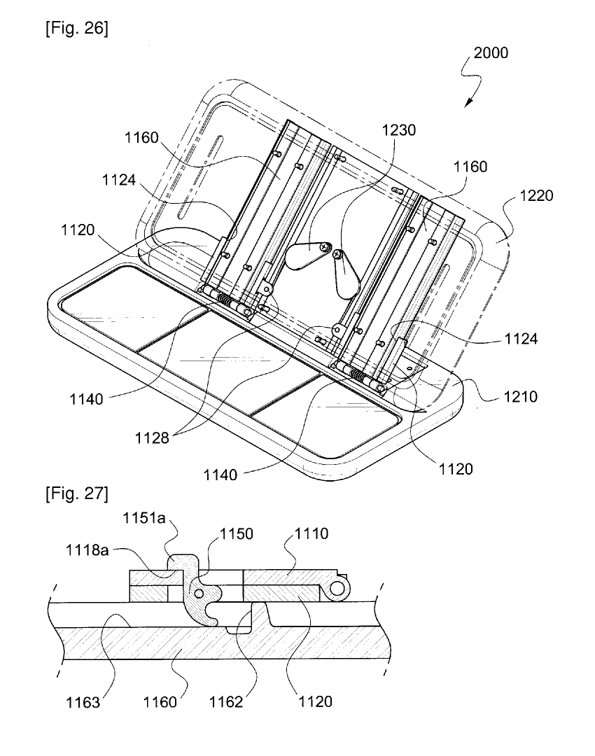

FIG. 24 is a view showing a closed state of the slide opening/closing-type apparatus according to the present invention, FIG. 25 is a view showing a state where the second body has been moved along a first guide part, and FIG. 26 is a view showing a state where the second body is erected on a slant after moving along the first guide part.

As shown in FIG. 24, in a state where the second body 1220 is closed on the first body 1210, an upper end of each guided plate 1160 is assembled with each rail member 1120, and one end of each elastic device 1230, which is connected with the elastic device connecting hole 1128 of the rail member 1120, is arranged upward.

In the state of FIG. 24, when the second body 1220 is pushed upward, the guided plate 1160 assembled with the second body 1220 moves upward through guiding operation of the first guide part 1124 so that the second body 1220 including the first sliding member 1330 and the second sliding member mounted on the first sliding member also moves upward as shown in FIG. 25. In a procedure where the state of FIG. 24 is changed to the state of FIG. 25, since the locking jaw 1151 of the swing member 1150 has been locked in the locking part 1118 of the rail member 1120, the guided plate 1160 smoothly slides regardless of the effects of torque of the hinge spring 1140.

In the state of FIG. 24, because each elastic device 1230 applies downward force to the second body 1220, the second body 1220 maintains a state where it has moved downward in the maximum degree without clearance.

When the second body 1220 is pushed to a middle degree, afterward, the elastic device 1230 changes the direction of its force to apply the force in a direction where the second body 1220 is pushed upward.

When the second body 1220 is elevated upward to the maximum degree, the swing-triggered part 1153 of the swing member 1150, which has been described above, is locked in the swing-triggering part 1162 and rotates so that the locking jaw 1151 escapes from the locking part 1118. Accordingly, the rail member 1120 is unfolded from the connecting member 1110 due to the torque of the hinge spring 1140. Therefore, as shown in FIG. 26, the guided plates 1160 and the second body 1220 are unfolded so that the second body 1220 is inclined against the first body 1210.

In a case where the user wants to again close the portable electronic apparatus after using it in the state of FIG. 26, when the user positions the second body 1220 in parallel with the first body 1210 by pressing the second body and pulls the second body 1220 downward a little, the swing-triggered part 1153 of the swing member 1150 escapes from the swing-triggering part 1162 and rotates in a direction opposite to the previous direction. Accordingly, the locking jaw 1151 is locked in the locking part 1118. After the locking jaw 1151 has been locked in the locking part 1118, the locking jaw 1151 takes the torque of the hinge spring 1140. Therefore, the guided plate 1160 smoothly slides along the first guide part 1124 regardless of the effects of the torque of the hinge spring 1140.

FIG. 27 is a sectional view showing another embodiment of a structure where the swing member, the swing-triggering part, and the swing-triggered part are assembled.

As shown in FIG. 27, as the case may be, it is also possible that the swing-triggering part 1162 is formed on a bottom part 1163 of the guided plate 1160, and the swing member 1150 is installed in such a manner it can rotate about a rotational shaft installed on the bottom surface 1163 of the rail member 1120 in parallel with the surface of the rail member 1120 so that the locking jaw 1151a is locked in the locking part 1118a of the connecting member 1110 or be released. The remaining configurations are the same as those described above.

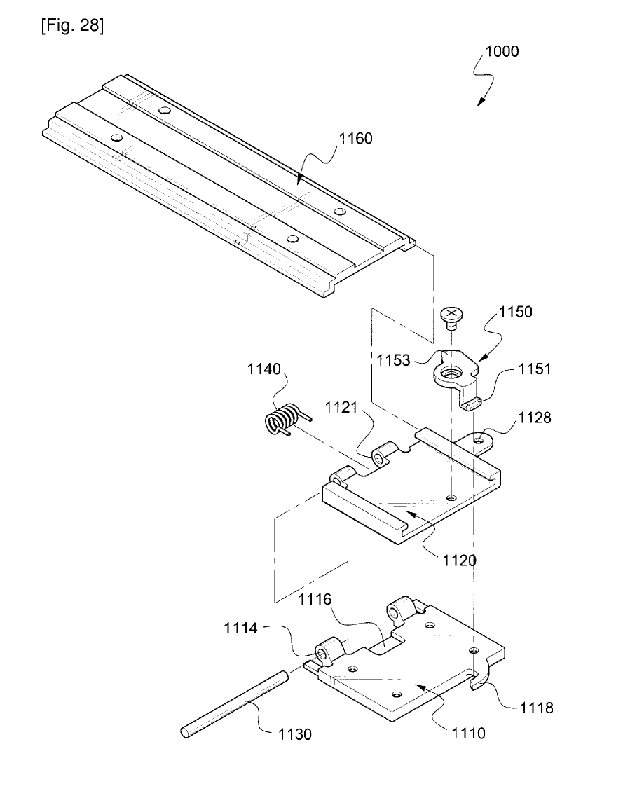

FIG. 28 is an exploded perspective view showing another embodiment of a slide hinge device according to the present invention.

As the case may be, it is possible that the first and second through-holes are not formed on the connecting member 1110 and the rail member 1120, the swing member 1150 is installed on the end of the rail member 1120, and the locking part 1118 is formed on the end of the connecting member 1110, so that the locking jaw 1151 is locked in the locking part 1118 according to the rotational angle of the swing member 1150 to be in a folded state or is released from the locking part to allow the rail member 1120 to be unfolded from the connecting member 1110.

Also, as the case may be, the locking part 1118 can extend from the connecting member toward the upper surface of the rail member 1120. In this case, it is not necessary that the locking jaw 1151 is formed on the lower side of the swing member, which extends downward, as shown in FIG. 28.

The remaining configurations are the same as those described above through FIGS. 13 to 21.

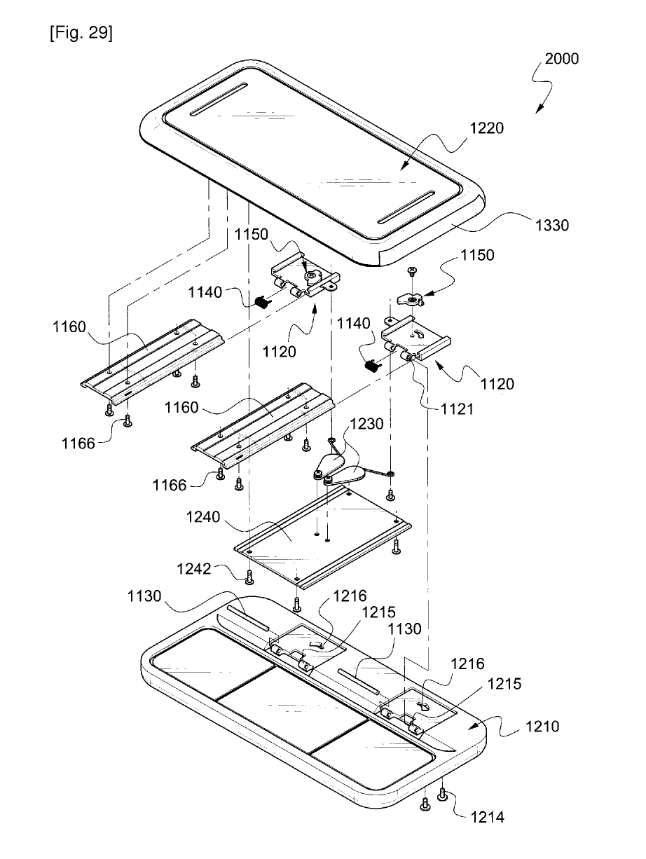

FIG. 29 is an exploded perspective view showing a slide opening/closing-type electronic apparatus according to another embodiment of the present invention.

As the case may be, it is possible that, without the connecting member in the above described embodiment, a hinge part 1215 is integrally formed on a body, such as the first body 1210, etc., of the sliding opening/closing -type electronic apparatus 2000, and a locking part 1216 is formed on one portion of the hinge part 1215.

In this case, the rail member 1120 can be rotatably installed on the hinge part 1215 by using the hinge shaft 1130 and the hinge spring 1140.

The remaining configurations are the same as those described above.

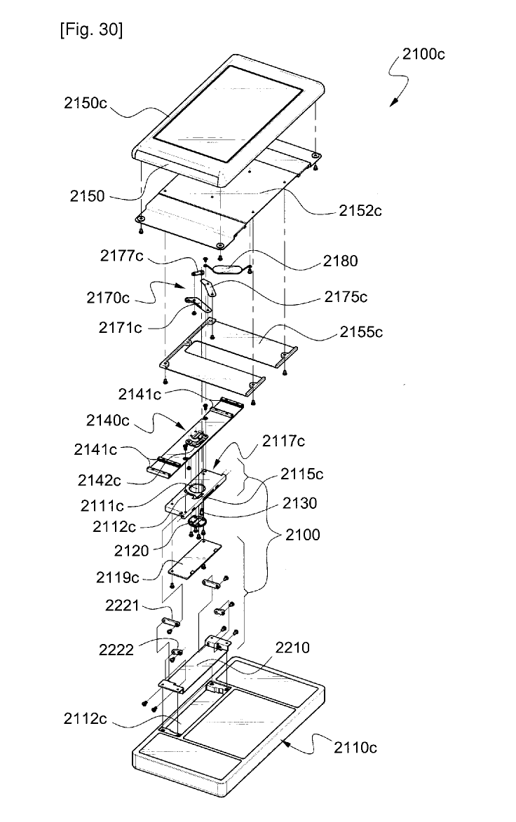

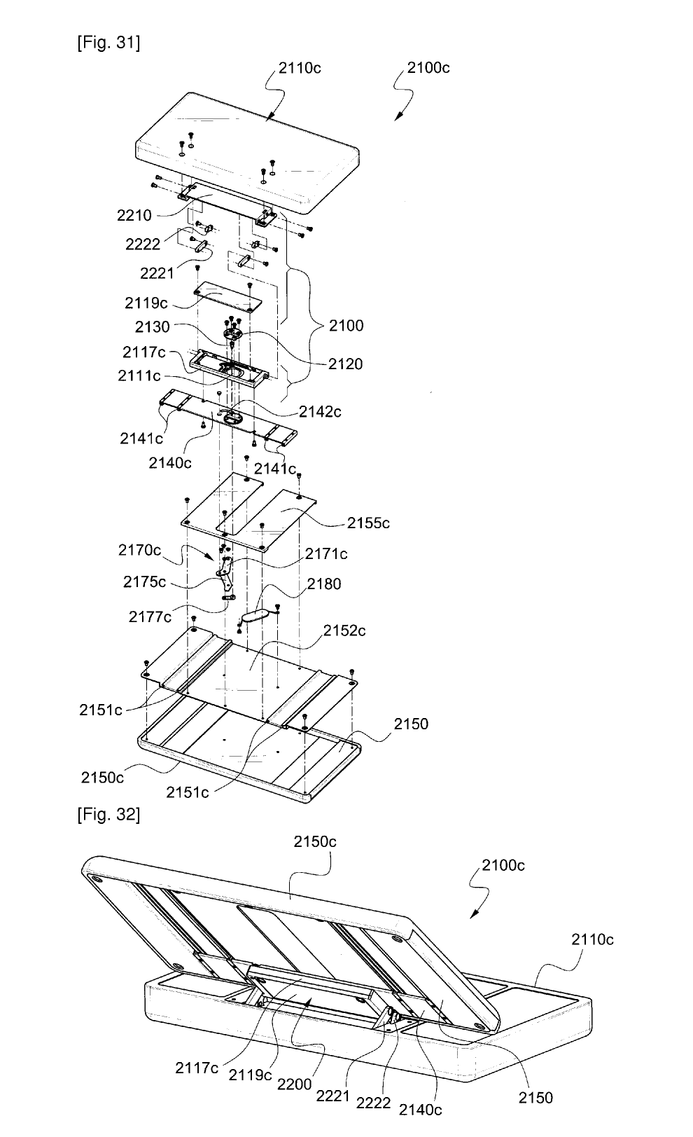

FIG. 30 is an exploded perspective view of a portable electronic apparatus, in which a structure between the first body and the first sliding member according to another embodiment of the present invention is shown, and FIG. 31 is an exploded perspective back view of the portable electronic apparatus of FIG. 30.

As shown, a recess part 2112c for installation of a tilting part 2100 is formed on an upper surface of the first body 2110c of the portable electronic apparatus 2100c. The tilting part 2100 is installed on the recess part 2112c.

The tilting part 2100 includes a tilting link installation part 2210 having stepped inner surfaces on both sides thereof. The tilting link installation part 2210 can be integrally formed on the first body 2110c. A pair of tilting links 2221 and 2222, which have lengths different from each other, is rotatably installed on each inner surface of both sides of the tilting link installation part 2210. Although two pairs of tilting links 2221 and 2222 are installed according to the present embodiment, as the case may be, a pair of tilting links 2221 and 2222 can be installed, and the length difference between the tilting links 2221 and 2222 can be changed according to a tilting angle. A tilting plate 2117c, on which a slide limitation guide path 2112c and a rotation limitation part 2115c are formed, is installed on each upper end of the tilting links 2221 and 2222. In the embodiment, the rotation limitation part 2115c can be formed with the shape of a circular arc of an ellipse or with other curve shape, furthermore, with a linear shape. As the case may be, the rotation limitation part can be formed along a path shaped like a circular arc having a uniform radius of curvature. This will be described in detail below when describing a link device 2170c. The tilting plate 2117c can be be erected with a predetermined angle respective to the first body 2110c according to a rotational angle of the tilting links 2221 and 2222 or can be horizontally spread on the first body 2110c in parallel. A hole 2111c for installing a rotational shaft member 2120 is formed on the tilting plate 2117c. The rotational shaft member 2120 is installed through the hole 2111c in such a manner that it is rotated on its own axis, and a plate member 2119c for supporting the rotational shaft member 2120 is installed on the bottom surface of the rotational shaft member 2120.

A rail member 2140c is assembled with the rotational shaft member 2120 so that it is rotatably installed on the tilting plate 2117c. A pair of guide parts 2141c is installed on each edge of both sides of the rail member 2140c. The guide parts are installed so as to allow the second body 2150c with a large width to stably slide. As the case may be, it is natural that a slide guide path can be formed as shown in the above described embodiment.

A first auxiliary member 2152c and a second auxiliary member 2155c, which are assembled with the bottom surface of the first sliding member 2150 assembled with the bottom surface of the second sliding member installed on the bottom surface of the second body 2150c, are installed on the rail member 2140c. A pair of first guided part 2151c, which are assembled with the first guide parts 2141c, is formed on the left and right sides of the first auxiliary member 2152c. The second auxiliary member 2155c is assembled with the bottom surface of the first auxiliary member 2155c and has a U-shape having a central portion which is perforated. The second auxiliary member 2155c provides installation space for the link device 2170c and a slide elastic device 2180. The first guided parts 2151c can be directly formed on the bottom surface of the first sliding member 2150.

The slide elastic device 2180 is installed between the rail member 2140c and the second auxiliary member 2155c assembled with the second body 2150c.

The link device 2170c in the embodiment includes three link members. In more detail, the link device 2170c includes a first link member 2171c rotatably installed on the rail member 2140c, a second link member 2175c, which has one end rotatably connected with the first link member 2171c and the other end rotatably supported by the second body 2150c, and a third link member 2177c, which is rotatably installed on one portion of the first link member 2171c and has one end connected with an interlocking member 2130. Accordingly, it is unnecessary that the rotation limitation part 2115c, which is assembled with the interlocking member 2130 to limit the rotation of the second body 2150c when the second body 2150c slides, is formed along a circular arc centering a rotational center of the first link member 2171c, and the rotation limitation part 2115c can be formed with a curved shape, such as an elliptical shape, etc. As the case may be, the rotation limitation part 2115c may also be formed with a linear shape in the embodiment. As the case may be, two link members may be formed.

Also, in this embodiment, since the interlocking member 2130 is positioned in a part of the rotation limitation part 2115c, which is spaced from the slide limitation guide path 2111c, in a state where the second body 2150c has been closed. Therefore, the second body 2150c doesn't rotate in the closed state. Meanwhile, when the second body 2150c is opened through sliding, the interlocking member 2130 is moved toward the slide limitation guide path 2112c by operation of the link device 2170c, thereby escaping from the rotation limitation part 2115c. Therefore, the second body 2150c can rotate in a state where it has been opened through sliding.

An interlocking member guide path 2142c formed on the rail member 2140c is formed with a shape identical to the shape of the rotation limitation part 2115c. The rotation limitation part 2115c is connected with one end of the slide limitation guide path 2112c and is arranged in such a manner that the rotation limitation part is overlapped with the interlocking member guide path 2142c when the second body 2150c slides or is closed.

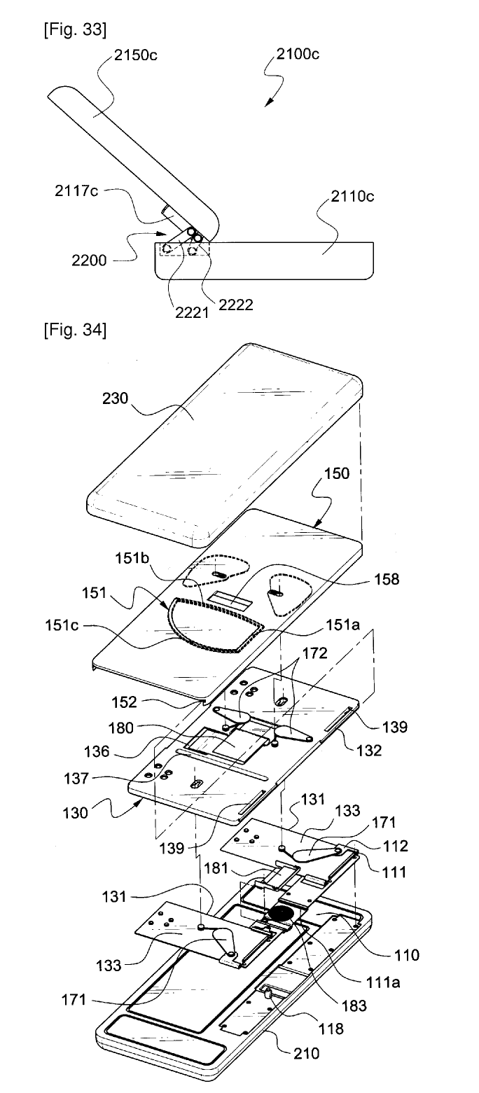

FIG. 32 is a perspective rear view showing a state where the second body of the assembled portable electronic apparatus of FIG. 30 is tilted after sliding along the first guide part, and FIG. 33 is a side view of FIG. 32.

In a state where the second body 2150c has been opened along the first guide part 2141c through sliding, when the second body 2150c is lifted upward a little, the tilting links 2221 and 2222, which lies down, stands up and lifts the tiling plate 2117c upward a little in such a manner that a rear part of the tilting plate 2117c is simultaneously left higher, so that the tilting plate 2117c is tilted with an inclination of a predetermined angle. This tilting angle is 90 degrees or less, and a proper tilting angle is 30 degrees or 45 degrees. Herein, the tilting links 2221 and 2222 have to be arranged while missing each other in the left-right direction as shown in FIG. 32 so as to allow the tilting plate 2117c to be tilted or to be spread in parallel with the second body 2150c without interference with each other.

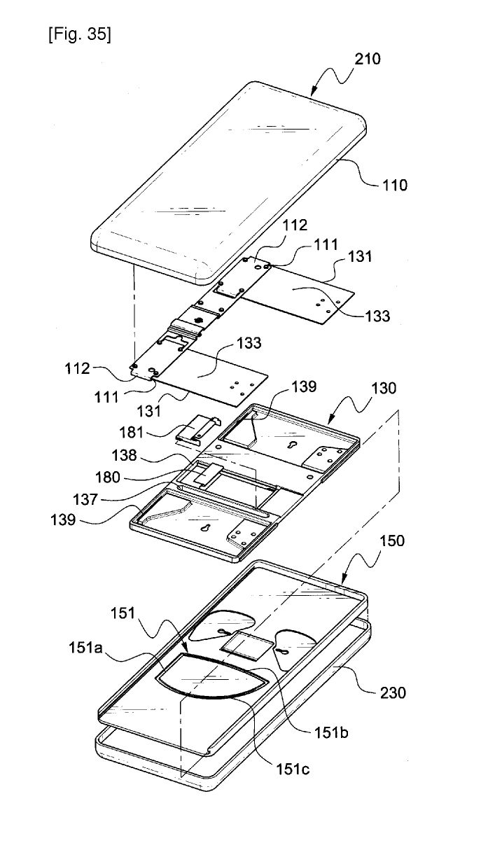

FIG. 34 is an exploded perspective view showing the slide opening/closing-type electronic apparatus according to another embodiment of the present invention, and FIG. 35 is an exploded perspective back view of the slide opening/closing-type electronic apparatus of FIG. 34.

In the embodiment shown in FIGS. 34 and 35, instead of the first engaging part, the first engaged part, the second engaging part, and the second engaged part in the embodiment described above, a limiting protuberance 118 is formed on the base member 110 in such a manner that it protrudes upward from the base member. Also, a through-hole 137 allowing the limiting protuberance 118 to pass through the through-hole, is formed on the first sliding member 130. A path limiting part 151, which allows an end of the limiting protuberance 118 to be inserted therein and limit the movement path of the limiting protuberance 118, is formed on the second sliding member 150 so as to limit a movement range and a movement path of the first sliding member 130 and the second sliding member 150 respective to each other and respective to the base member 110.

As shown in FIGS. 34 and 35, the limiting protuberance 118 is formed on one portion of the base member 110 in such a manner that it protrude upward from the base member. It is preferable that the limiting protuberance 118 has a circular section and is installed near an edge of a right side of the base member 110.

The through-hole 137, which allows the limiting protuberance 118 to pass therethrough in an upper direction, is formed on the first sliding member 130. The through-hole 137 allows the limiting protuberance 118 to pass via the through-hole and is installed with a length and a path allowing the first sliding member 130 to slide along the first guide part 111 without interruption from the limiting protuberance 118. The through-hole 137 is interlocked with the limiting protuberance 118 so as to limit a distance where the first sliding member 130 can slide in a first direction and also prevent the first sliding member 130 from escaping from the first guide part 111. The through-hole 137 is preferably installed in a transverse direction of the first sliding member 130 while having a linear shape.

The path limiting part 151 is formed on the bottom surface of the second sliding member 150. The path limiting part 151 is assembled with the end of the limiting protuberance 118, which has passed via the through-hole 137, and is guided while its movement path is limited. It is preferable that the path limiting part 151 has a groove-shape. However, as the case may be, a groove may be formed on an end of the limiting protuberance 118, and the path limiting part 151 may have a shape protruding downward in a small degree. Such path limiting part 151 can be formed along the closed path. As shown in FIGS. 34 and 35, in a case where the path limiting part 151 is formed along a closed path, a cover, that is, the second body 230 can perform a limitless circulation operation of moving while changing its position according to the order of a position where it has been closed, a position where it has been opened in a second direction, a position where it has been opened in the first direction, and a position where it has been closed, and can also perform a limitless circulation operation in the opposite direction.

In a case where an operation of the second body 230 being changed from the opened state in the first direction to the opened state in the second direction, or an opposite operation thereof is not necessary, it is enough that the path limiting part 151 is formed with an L-shape. That is, in a case where the first body 210, which has been opened in the first direction, is intended to be opened in the second direction, and in a case where the first body 210 is opened in the second direction after returning to the closed state, it is enough that the path limiting part 151 is formed with an L-shape, and not with a closed path-shape.

In FIGS. 34 and 35, the path limiting part 151 has a first path limiting part 151a allowing the second sliding member 150 to slide without interruption from the limiting protuberance 118 when the second sliding member 150 slides along the second guide part 132. The first path limiting part 151a is preferably formed with a linear shape in a direction where the second guide part 132 is arranged.

The path limiting part 151 also includes a second path limiting part 151b. The second path limiting part 151b is a part guided by the limiting protuberance 118 when the second sliding member 150 is opened in the second direction and preferably has a roughly linear shape having a part curved toward an upper side a little.

Moreover, the path limiting part 151 has a third path limiting part 151c, which is interlocked with the limiting protuberance 118 according to the location of the first sliding member 130 when the first sliding member 130 moves along the first guide part 111, thereby adjusting the upper or lower position of the second sliding member 150 on the second guide part 132. Although it is preferable that the third path limiting part 151c has a curve shape, it may also have a linear shape. However, the third path limiting part 151c has at least one side, which is slanted respective to a horizontal direction.

Accordingly, the path limiting part 151 may have a closed path so that the second sliding member 150 or the second body 230 can perform a limitless circulation opening/closing operation where it moves while changing its position according to the order of the closed position, the opened position in the first direction, and the opened position in the second direction, or according to the reverse order.

In a case where it is unnecessary that the opened state in the first direction is directly converted to the opened state in the second direction, or vice-versa, the path limiting part 151 may have an L-shape without the third limiting part 151c. Similarly, in a special case where the second body is allowed to be opened in the second direction after it is opened in the first direction, the path limiting part 151 may be configuration without at least one of the first path limiting part 151a and the second path limiting part 151b.

As shown, a cable supporter 181 for supporting one side of an FPC cable 180 is installed between two rail members 112. The cable supporter 181 is movably installed in the guide groove 111a arranged in the same direction of the first guide part 111, An end of the FPC cable 180 is inserted into the lower part of the cable supporter to be connected with the first body 210. A torsion spring 183 is installed below the cable supporter 181. An inner end of the torsion spring 183 is fixed in the base member 110 and the outer end thereof is connected with one portion of the cable supporter 181. Accordingly, the cable supporter 181 receives elastic force in a direction where the first sliding member 130 is opened in the first direction. However, since the cable supporter 181 is locked in a locking stepped part 138 formed on the bottom surface of the first sliding member 130 in the state where the first sliding member 130 has been closed, the cable supporter 181 can not move. When the first sliding member 130 is opened in the first direction, the cable supporter moves due to elastic force of the torsion spring 183 in a direction where the first sliding member 130 moves, thereby preventing a part of the FPC cable 180, which escapes from the base member 110, from being exposed to the outside through the bottom surface of the first sliding member 130. When the first sliding member 130 performs a returning operation, the cable supporter is locked in the locking stepped part 138 of the bottom surface of the first sliding member 130 so that it returns the original position together with the first sliding member.

In the embodiment, the first elastic device 171 has one end rotatably connected with the base member 110 through the guide rail 112 and the other end rotatably connected with the first sliding member 130.

Also, each second elastic device 172 has one end rotatably connected with the first sliding member 130 and the other end rotatably connected with the second sliding member 150.

One end of each first guided plate 133 is fixed on the bottom surface of the first sliding member 130, and a bent portion of the other end thereof is fixedly inserted into a slot 139 formed on the right end of the first sliding member 130. In the embodiment, it is necessary that through-holes 136 and 158, which allow the FPC cable, etc. to pass via the through-holes, are formed on the first sliding member 130 and the second sliding member 150, respectively.

Except of the above described configuration, the remaining configurations are the same as those described above through FIGS. 1 to 4.

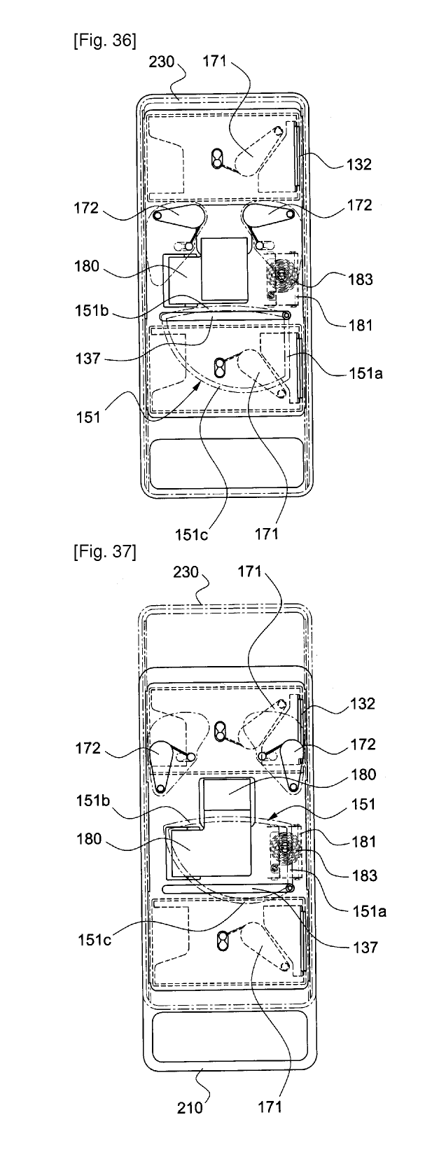

FIGS. 36 to 39 are plane views showing a state where the first body has been closed, a state where the first body has been opened in a second direction, a state where the opened state in the second direction is converted to an opened state in a first direction, and the state where the first body has been opened in the first direction, respectively.

The operational procedure of the portable electronic apparatus according to the present invention will be described below with reference to FIGS. 34 to 36.

In the state of FIG. 36, when the first body 210 is pushed upward, the second sliding member 150 slides along the second guide pat 132 and is opened in the second direction. At this time, the second elastic device 172 rotates about its point supported by the first sliding member 130. While the rotation, the second elastic device 172 applies elastic force upward to the second sliding member 150 after a position at which the supporting points of both sides of the second elastic device are leveled with each other. Then, the second body 230 is opened in the second direction as shown in FIG. 37. At this time, the FPC cable 180 is unfolded a little in the second direction. This can be checked if respective states of the FPC cable 180 of FIGS. 36 and 37 are compared with each other. In the state where the second body 230 has been opened in the second direction, the second elastic device 172 applies elastic force upward to the second sliding member 150 to maintain a stable state of the second sliding member.

Meanwhile, as the second sliding member 150 moves upward, the first path limiting part 151a locked with the limiting protuberance 118 moves upward, that is, the first path limiting part 151a moves upward in such a manner that it is guided by the limiting protuberance 118 while maintaining the state limited in the left-right direction. The limiting protuberance 118 is positioned at a lower end of the first path limiting part 151a when the second sliding member 150 or the second body 230 has been opened.

When the user wants to covert the state opened in the second direction as shown in FIG. 37 to the opened state in the first direction, the user slides the second body 230 rightward, the first sliding member 130 slides rightward along the first guide part 111.

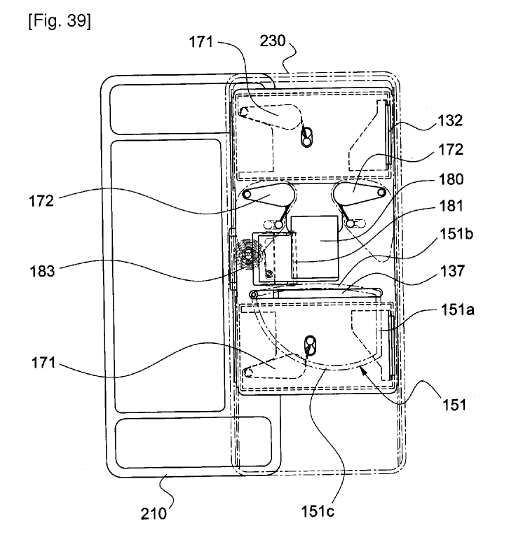

At this time, the first sliding member 130 is assembled with the limiting protuberance 118 via the through-hole 137, and the second sliding member 150 is assembled with the limiting protuberance 118 via the third path limiting part 151c. The first sliding member 130 linearly moves rightward along the first guide part 111. At this time, the limiting protuberance 118 doesn't interrupt rightward movement of the first sliding member 130. The second sliding member 150 is left upward a little and again moves downward through mutual operation between the limiting protuberance 118 and the third path limiting pat 151c so that the second sliding member 150 becomes a state shown in FIG. 39, which is the same as the state where the second body 230 is opened in the first direction through rightward sliding. At this state, the first elastic device 171 rotates about a supporting point of the guide rail 112 fixed in the base member 110 and slides the first sliding member 130 rightward due to elastic force from the moment when supporting points of both sides of the first elastic device 171 pass a collinear line so that a state where the second body 230 is opened in the first direction is formed as shown in FIG. 39. At this time, the first path limiting part 151a moves along the limiting protuberance 118 in a distance from the right end to the left end thereof. At this time, the limiting protuberance 118 moves the second sliding member 150 upward a little and again moves it downward through the first path limiting part 151a, thereby forming the state of FIG. 39. In the state where the second body 230 has been opened in the second direction, when the second body 230 is pushed in the left direction, the second body 230 becomes the closed state of FIG. 36. In this procedure, the limiting protuberance 118 performs a mutual operation respective to the third path limiting part 151c.

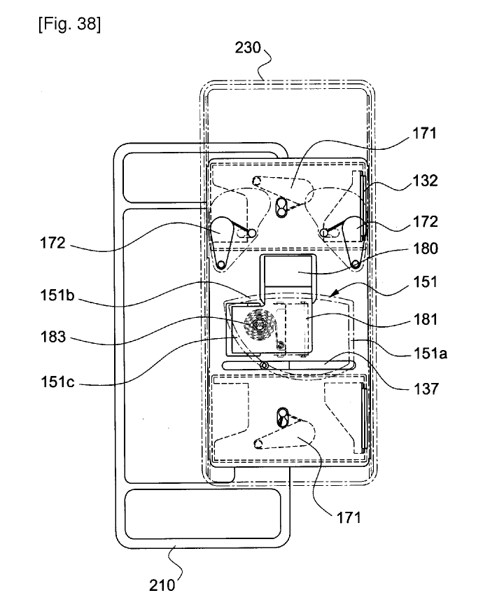

As the case may be, it is possible that the state of FIG. 39 is converted to the opened state in the second direction as shown in FIG. 37. Such state-conversion is also possible between the state of FIG. 36 and the state of FIG. 37 and between the state of FIG. 37 and the state of FIG. 38. That is, in the present invention, it is possible that a current state returns the previous state or is converted to the state in the next step.

Meanwhile, in the procedure where the state of FIG. 37 is converted to the state of FIG. 39, when the first sliding member 130 slides rightward, the FPC cable supporter 181 prevents the lower part of FPC cable 180, which has been folded, from being exposed to the outside by covering the lower part while moving rightward due to the torsion spring 183. When the first sliding member 130 returns to the original state to a predetermined degree, the FPC cable supporter 181 is locked in the locking stepped part 138 formed on the bottom surface of the first sliding member 130 and is moved leftward to return to the original position shown in FIG. 36.

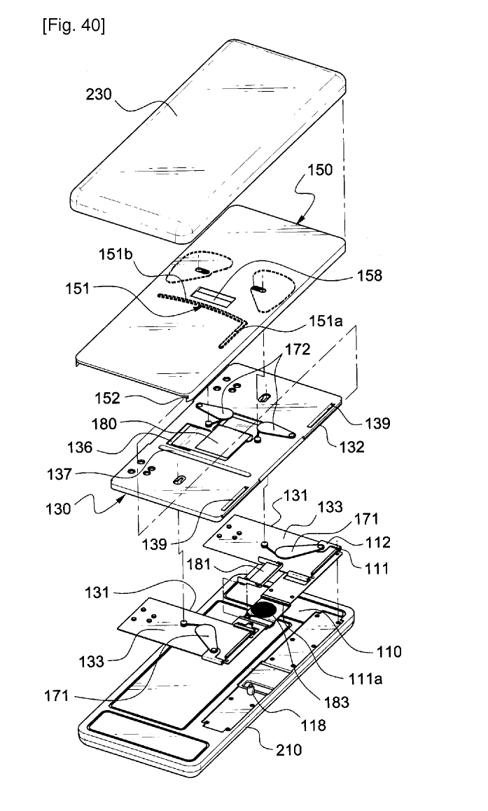

FIG. 40 is an exploded perspective view showing a modified embodiment of FIG. 34.

As the case may be, the path limiting part 151 may have the first path limiting part 151a and the second path limiting part 151b arranged with an L-shape without the third path limiting part. In this case, when it is required to open the first body 210 in the second direction after opening it in the first direction, or when it is required to open the first body 210 in the first direction after opening it in the second direction, the first body 210 has to undergo a closed state. The remaining configurations are the same as those of FIG. 34.

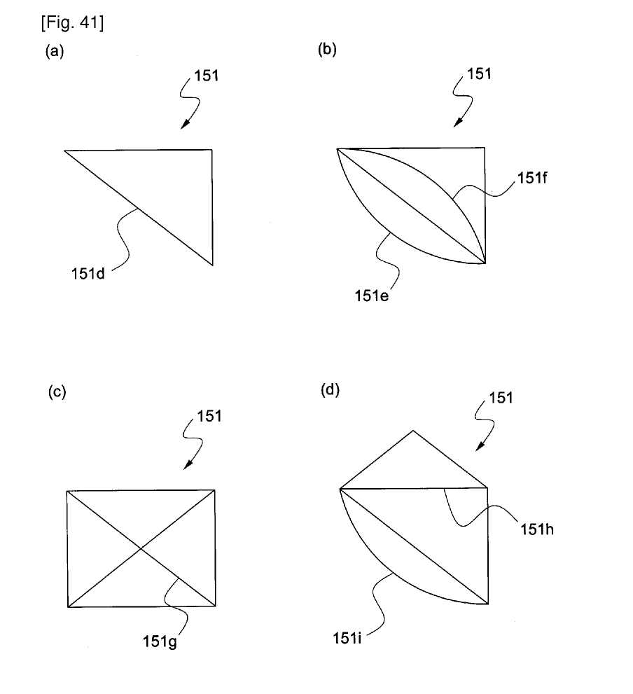

FIG. 41 is a view showing modified embodiments of a path limiting part.

The path limiting part 151 can be variously shaped as shown in FIG. 41. That is, as shown in FIG. 41a, the path limiting part 151 is formed with a right angled triangle-shape so that it can allow the cover to move along a linear path 151d with the shortest distance when the cover of the opened state in the first direction is converted to the opened state in the second direction or when the cover of the opened state in the second direction is converted to the opened state in the first direction.

As the case may be, as shown in FIG. 41b, the path limiting part 151 may be shaped in such a manner that curved paths 151e and 151f are further formed at the upper and lower sides of the linear path 151d.

Furthermore, as shown in FIG. 41c, the path limiting part 151 may be formed with a rectangular shape, and diagonal paths 151g may be further formed along diagonal lines of the rectangular shape. Also, as the case may be, as shown in FIG. 41d, the path limiting part 151 may be formed with a trapezoid-shape and have a diagonal path 151h and a curve path 151i.

As described above, it is understood by those skilled in the art that it is possible to implement numerous path limiting parts 151 with various shapes.

### INDUSTRIAL APPLICABILITY

The slide opening/closing-type device according to the present invention may be used as a slide opening/closing-type device of a portable electronic apparatus.

The portable electronic apparatus according to the present invention may be used in manufacturing a slide opening/closing-type portable electronic apparatus.

1. A slide-type opening/closing device comprising:
a base member, on which first guide parts are installed;
a first sliding member having first guided parts, which are movably engaged with the first guide parts, and second guide parts installed on the first sliding member in a direction different from a direction of the first guide parts; and
a second sliding member having second guided parts movably engaged with the second guide parts.

2. The slide-type opening/closing device as claimed in claim 1, wherein a first engaging part and a first engaged part are installed on the base member and the second sliding member, respectively in such a manner that the first engaging part and the first engaged part are engaged with each other so as to allow the first sliding member to slide along the first guide parts in a state where the second sliding member does not slide along the second guide parts, and so as to prevent the first sliding member from sliding along the first guide part in a state where the second sliding member has slid along the second guide parts.

3. The slide-type opening/closing device as claimed in claim 2, wherein the first engaging part is a protuberance formed on the base member, and the first engaged part is a groove or a protuberance, which is formed on the second sliding member and has a gap allowing the first engaging part to pass through the gap in a state where the second sliding member does not slide along the second guide parts, or the first engaged part is a protuberance formed on the second sliding member, and the first engaging part is a groove or a protuberance, which is formed on the base member and has a gap allowing the first engaged part to pass through the gap in a state where the second sliding member does not slide along the second guide parts.

4. The slide-type opening/closing device as claimed in claim 1, wherein a second engaging part and a second engaged part are installed on the base member and the second sliding member in such a manner that the second engaging part and the second engaged part are engaged with each other so as to allow the second sliding member to slide along the second guide parts in a state where the first sliding member does not slide along the first guide parts, and so as to prevent the second sliding member from sliding along the second guide parts in a state where the first sliding member has slid along the first guide parts.

5. The slide-type opening/closing device as claimed in claim 4, wherein the second engaging part is a protuberance formed on the base member, and the second engaged part is a protuberance, which is formed on the second sliding member and has a gap allowing the second engaging part to pass through the gap in a state where the first sliding member does not slide along the first guide parts, or the second engaged part is a protuberance formed on the second sliding member, and the second engaging part is a groove or a protuberance, which is formed on the base member and has a gap allowing the second engaged part to pass through the gap in a state where the first sliding member does not slide along the first guide parts.

6. The slide-type opening/closing device as claimed in claim 1, wherein each first guide part is formed in such a manner that a rail member is attached onto the base member, the rail member having a pair of guide paths, which are positioned in parallel with an vertical interval between them and are arranged in a left-right direction.

7. The slide-type opening/closing device as claimed in claim 1, wherein the second guide parts are shaped like each groove or each protuberance formed along both side surfaces of the first sliding member in an up-down direction, and the second guided parts are shaped like each protuberance or each groove formed along inner surfaces of downward protruding parts, which protrude downward along each edge of both sides of the second sliding member and are arranged outside of both side surfaces of the first sliding member.

8. The slide-type opening/closing device as claimed in claim 1, wherein each first guide part is locked in the base member or a part connected with the base member and is folded before the first sliding member is opened through sliding along the first guide part, and in a state where the first sliding member has been opened through sliding along the first guide part, the first guide part is released from the base member or the part connected with the base member so that the first guide part can be erected on a slant respective to the base member.

9. The slide-type opening/closing device as claimed in claim 8, wherein the first guide part and the first guided part are installed through a slide hinge device installed between the base member and the first sliding member, and the sliding hinge device includes a hinge device, in which a connecting member, which has a locking part formed on the connecting member and is connected with the base member, and a rail member having the first guide parts, are foldably connected with each other, the hinge device receiving elastic force in a direction where the connecting member and the rail member are unfolded through a hinge spring, a guided plate, which is slidably assembled with the first guide parts, has a swing-triggering part formed on one end of the guided plate, and is installed on the first sliding member, and a swing member including a locking jaw, which is rotatably installed on the rail member and is locked in or released from the locking part according to a rotational angle, a swing-triggered part, which is locked in the swing-triggering part according to movement position of the guided plate and rotates so as to allow the locking jaw to be released from the locking part, or is released from the swing-triggering part and rotates in an opposite direction so as to allow the locking jaw to be locked in the locking part.

10. The slide-type opening/closing device as claimed in claim 8, wherein the first guide part and the first guided part are installed through a slide hinge device installed between the base member and the first sliding member, and the slide hinge device includes a locking part and a hinge part, which are formed on the first sliding member, a rail member, which has first guide parts, is rotatably installed on the hinge part to be foldably connected with the first sliding member, and receives elastic force by a hinge spring in a direction where the rail member is unfolded respective to the first sliding member, a guided plate, which is slidably assembled with the first guide parts and has a swing-triggering part formed on one end of the guided plate, and a swing member including a locking jaw, which is rotatably installed on the rail member and is locked in or released from the locking part according to a rotational angle, and a swing-triggered part, which is locked in the swing-triggering part according to movement position of the guided plate and rotates so as to allow the locking jaw to be released from the locking part, or is released from the swing-triggering part and rotates in an opposite direction so as to allow the locking jaw to be locked in the locking part.

11. The slide-type opening/closing device as claimed in claim 1, wherein each first guide part is installed on the base member through a tilting part, which is tiltably installed on the base member, and can be bent upward or can be spread after being bent upward, so that the first sliding member can be bent respective to the base member with an acute angle in a state where the first sliding member has been opened through sliding along the first guide part.

12. The slide-type opening/closing device as claimed in claim 11, wherein the tilting part includes a tilting link installation part, which is formed on the base member and has at least one stepped inner surface, a tilting plate installed near the tilting link installation part in such a manner that the tilting plate can rotate in a tilting direction, and a pair of tilting links having different lengths, each tilting link being rotatably installed on the tilting link installation part and being connected with the tilting plate.

13. The slide-type opening/closing device as claimed in claim 11, wherein the first guide part is installed on the tilting part in such a manner that the first guide part can rotate about a rotational shaft member and allows the first sliding member to be bent with an acute angle respective to the base member in a state where the first sliding member has been opened through rotation.

14. The slide-type opening/closing device as claimed in claim 1, wherein a limiting protuberance protruding upward is formed on the base member, a through-hole, which allows the limiting protuberance to pass via the through-hole and is not interrupted from the limiting protuberance when the first sliding member slides along the first guide part, is formed on the first sliding member, and a path limiting part is formed on the second sliding member along a predetermined path so that the path limiting part is engaged with the limiting protuberance passed through the first sliding member so as to limit movement path of the second sliding member.

15. The slide-type opening/closing device as claimed in claim 14, wherein the path limiting part is formed along a closed path, and the closed path is one of a path obtained by combining liner paths, a path obtained by combining curve paths, and a path obtained by combining liner paths and curve paths.

16. The slide-type opening/closing device as claimed in claim 14, wherein the path limiting part includes a first path limiting part, which allow the second sliding member to be free from the limiting protuberance when the second sliding member slides along the second guide parts, and a second path limiting part, which allows the first sliding member to be free from the limiting protuberance when the first sliding member slides along the first guide parts.

17. The slide-type opening/closing device as claimed in claim 1, wherein a guide groove, which is arranged in a same direction of the first guide part, is formed on the base member, a cable supporter, which is supported by a torsion spring in a direction where the cable supporter escapes from the base member, is movably installed on the guide groove, and a locking stepped part is formed on an bottom surface of the first sliding member, the locking stepped part holding the cable supporter in a closed state of the first sliding member and releases the cable supporter when the first sliding member is opened so that the cable supporter is moved due to elastic force of the torsion spring to cover a FPC cable escaping from the base member, and being locked in one portion of the cable supporter when the first sliding member returns to its original position so as to allow the cable supporter to return its original position.

18. The slide-type opening/closing device as claimed in claim 1, wherein first keys are installed on an upper surface of the base member, which is exposed to an outside when the first sliding member is opened along the first guide part, and second keys are installed on an upper surface of the first sliding member, which is exposed to an outside when the second sliding member is opened along the second guide part.

19. The slide-type opening/closing device as claimed in claim 1, wherein the first sliding member has a length shorter than each length of the base member and the second sliding member and is installed at a position where an upper surface of the first sliding member isn't is not exposed to an outside even though the first sliding member is opened through sliding along the first guide part, or the second sliding member is opened through sliding along the second guide part, and first keys used when the first sliding member is opened and second keys used when the second sliding member is opened are installed on an upper surface of the base member.

20. The slide-type opening/closing device as claimed in claim 1, wherein a first elastic device, which has one end rotatably connected with the base member and another end rotatably connected with the first sliding member so as to slide the first sliding member leftward or rightward respective to the base member according to position of the first sliding member, is installed between the base member and the first sliding member, and a second elastic device, which has one end rotatably connected with the first sliding member and another end rotatably connected with the second sliding member so as to slide the second sliding member upward and downward respective to the first sliding member according to position of the second sliding member, is installed between the first sliding member and the second sliding member.

21. The slide-type opening/closing device as claimed in claim 1, wherein the base member is integrally formed on a lower body of a portable electronic apparatus, and the second sliding member is integrally formed on a cover of the portable electronic apparatus.

22. A portable electronic apparatus comprising:
a first body;
a second body; and
the slide-type opening/closing device in claim 1, which is installed between the first body and the second body to allow the second body to be selectively opened respective to the first body in a first direction or in a second direction.
